(19) United States
(12) Patent Application Publication
(10) Pub. No.: US 2025/0194345 A1
(43) Pub. Date: Jun. 12, 2025

(54) DISPLAY DEVICE AND METHOD FOR FABRICATION THEREOF

(71) Applicant: Samsung Display Co., LTD., Yongin-si (KR)

(72) Inventors: Won Je JO, Yongin-si (KR); Che Ho LEE, Yongin-si (KR); Sae Bom AHN, Yongin-si (KR); So Yeon JEONG, Yongin-si (KR); Jae Hyun KIM, Yongin-si (KR)

(21) Appl. No.: 18/786,829

(22) Filed: Jul. 29, 2024

(30) Foreign Application Priority Data
Dec. 7, 2023 (KR) 10-2023-0176570

(51) Int. Cl. H10K 59/122; H10K 59/12

(52) U.S. Cl. CPC H10K 59/122; H10K 59/1201

(57) ABSTRACT

A display device includes a first pixel electrode and a second pixel electrode spaced apart from each other on a substrate; a pixel defining layer disposed on the substrate and exposing the first pixel electrode and the second pixel electrode; a bank disposed on the pixel defining layer; a first light-emitting layer disposed on the first pixel electrode; a second light-emitting layer disposed on the second pixel electrode; a first common electrode disposed on the first light-emitting layer; and a second common electrode disposed on the second light-emitting layer and the bank and spaced apart from the first common electrode, where a width of the first common electrode and a width of the second common electrode are different from each other.

This application claims priority to Korean Patent Application No. 10-2023-0176570, filed on Dec. 7, 2023, and all the benefits accruing therefrom under 35 U.S.C. § 119, the content of which in its entirety is herein incorporated by reference.

### BACKGROUND

### 1. Field

The disclosure relates to a display device and a method for fabrication thereof.

### 2. Description of the Related Art

As an information society develops, the demand for a display device for displaying an image is increasing in various forms. For example, the display device is being applied to various electronic devices such as smartphones, digital cameras, laptop computers, navigation devices, and smart televisions. The display devices may be flat panel display devices such as liquid crystal display devices, field emission display devices, or organic light-emitting display devices. Among the flat panel display devices, the light-emitting display device may include a light-emitting element in which each of the pixels of a display panel may emit light by itself, thereby displaying an image without a backlight unit providing the light to the display panel.

Recently, the display devices are being applied to glasses-type devices to provide virtual reality and augmented reality. In order for the display device to be applied to the glasses-type device, the display device is desired to be implemented in a substantially small size of two inches or less, but needs to have a relatively high pixel integration in order to be implemented with relatively high resolution. In an embodiment, the display device may have a relatively high pixel integration of 400 pixels per inch (“PPI”) or more.

As described above, when the display device is implemented in a substantially small size but has relatively high pixel integration, it is difficult to implement light-emitting elements separated for each light-emitting area using a mask process because an area of a light-emitting area where the light-emitting elements are disposed is reduced.

### SUMMARY

Features of the disclosure provide a display device capable of forming light-emitting elements separated for each light-emitting area without using a mask process.

Features of the disclosure also provide a display device with substantially small light-emitting deviation between a plurality of light-emitting elements and excellent luminance.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a display device includes a substrate; a first pixel electrode and a second pixel electrode spaced apart from each other on the substrate; a pixel defining layer disposed on the substrate and exposing the first pixel electrode and the second pixel electrode; a bank disposed on the pixel defining layer; a first light-emitting layer disposed on the first pixel electrode; a second light-emitting layer disposed on the second pixel electrode; a first common electrode disposed on the first light-emitting layer; and a second common electrode disposed on the second light-emitting layer and the bank and spaced apart from the first common electrode, where a width of the first common electrode and a width of the second common electrode are different from each other.

In an embodiment, the width of the first common electrode may be smaller than the width of the second common electrode.

In an embodiment, the width of the first common electrode may be smaller than a width of the first pixel electrode, and the width of the second common electrode may be smaller than a width of the second pixel electrode.

In an embodiment, the first common electrode may be disposed on at least a portion of a first side surface of the bank and at least a portion of a second side surface different from the first side surface of the bank, and the second common electrode may be disposed on an entirety of a third side surface of the bank, at least a portion of a fourth surface different from the third side surface of the bank, and at least a portion of an upper surface of the bank.

In an embodiment, the bank may be a single film of metal or metal alloy.

In an embodiment, the display device may further include a first inorganic layer including a body portion disposed on the first common electrode, and a wing portion disposed on the bank and spaced apart from an upper surface of the bank; and a second inorganic layer including a body portion disposed on the second common electrode, and a connection portion disposed between the bank and the wing portion of the first inorganic layer.

In an embodiment, the connection portion of the second inorganic layer may include a side surface that further protrudes than a side surface of the bank and overlaps the first pixel electrode.

In an embodiment, the wing portion of the first inorganic layer may overlap the second common electrode in a thickness direction of the substrate.

In an embodiment, a lower surface of the connection portion of the second inorganic layer may contact the first inorganic layer.

In an embodiment, the second inorganic layer may further includes a first wing portion disposed on the wing portion of the first inorganic layer and spaced apart from an upper surface of the wing portion of the first inorganic layer; and a second wing portion disposed on the bank and spaced apart from the upper surface of the bank.

In an embodiment, the display device may further include a third pixel electrode disposed on the substrate and spaced apart from the first pixel electrode and the second pixel electrode; a third light-emitting layer disposed on the third pixel electrode; and a third common electrode disposed on the third light-emitting layer and the bank and spaced apart from the first common electrode and the second common electrode.

In an embodiment, the third common electrode is disposed on an entirety of a fifth side surface of the bank, an entirety of a sixth side surface different from the fifth side surface of the bank, and at least a portion of the upper surface of the bank.

In an embodiment, a width of the third common electrode disposed on the upper surface of the bank may be different from a width of the second common electrode disposed on the upper surface of the bank.

In an embodiment, the display device may further include an organic encapsulation layer disposed between the wing portion of the first inorganic layer and the first wing portion of the second inorganic layer.

In an embodiment of the disclosure, a display device includes a substrate, a first pixel electrode, a second pixel electrode, and a third pixel electrode spaced apart from each other on the substrate; a pixel defining layer disposed on the substrate and exposing the first pixel electrode, the second pixel electrode, and the third pixel electrode; a bank disposed on the pixel defining layer; a first light-emitting layer on the first pixel electrode and a first common electrode on the first light-emitting layer; a second light-emitting layer disposed on the second pixel electrode and a second common electrode on the second light-emitting layer; a third light-emitting layer disposed on the third pixel electrode and a third common electrode on the third light-emitting layer; and a first inorganic layer including a body portion disposed on the first common electrode, and a wing portion disposed on the bank and spaced apart from an upper surface of the bank, where the wing portion of the first inorganic layer overlaps the second common electrode and the third common electrode in a thickness direction of the substrate.

In an embodiment, the display device may further include a second inorganic layer including a body portion disposed on the second common electrode, and a connection portion disposed between the bank and the wing portion of the first inorganic layer, where the connection portion of the second inorganic layer includes a side surface that further protrudes than a side surface of the bank and overlaps the first pixel electrode.

In an embodiment, the first common electrode, the second common electrode, and the third common electrode have different cross-sectional shapes from each other.

In an embodiment of the disclosure, a method for fabrication of a display device includes forming a plurality of pixel electrodes spaced apart from each other on a substrate, forming a pixel defining material layer on the plurality of pixel electrodes, and forming a bank material layer on the pixel defining material layer; forming a first photoresist pattern on the bank material layer; etching the bank material layer that is not covered by the first photoresist pattern; and etching a side surface of the bank material layer and exposing a lower surface of the first photoresist pattern.

In an embodiment, the etching of the bank material layer that is not covered by the first photoresist pattern includes an anisotropic dry etching process, and the etching of the side surface of the bank material layer and the exposing the lower surface of the first photoresist pattern includes an isotropic wet etching process.

In an embodiment, the method may further include forming a first light-emitting layer on a first pixel electrode among the plurality of pixel electrodes and a first light-emitting pattern on the first photoresist pattern; forming a first common electrode on the first light-emitting layer and a first electrode pattern on the first light-emitting pattern; forming a first inorganic material layer on the first common electrode and the first electrode pattern; forming a second photoresist pattern on the first inorganic material layer overlapping the first pixel electrode; removing the first inorganic material layer that is not covered by the second photoresist pattern; and removing the first photoresist pattern, the second photoresist pattern, the first light-emitting pattern, and the first electrode pattern.

Details of other embodiments are included in the detailed description and drawings.

According to the display device and the method for fabrication thereof in an embodiment, the display device may include common electrodes of different shapes or widths for each light-emitting area. As a contact area between the common electrode and the bank increases, light-emitting characteristics of the display device may be improved.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other advantages and features of the disclosure will become more apparent by describing in detail embodiments thereof with reference to the attached drawings, in which:

FIG. 1 is a perspective view illustrating an embodiment of a display device;

FIG. 2 is a cross-sectional view of the display device of FIG. 1 viewed from a side;

FIG. 3 is a plan view illustrating an embodiment of an arrangement of light-emitting areas of the display device;

FIG. 4 is an exploded perspective view illustrating a stacking of a light-emitting element layer and a lower inorganic encapsulation layer in area A1 of FIG. 3;

FIG. 5 is a cross-sectional view illustrating an embodiment of a portion of the display device;

FIG. 6 is an enlarged view illustrating area A21 of FIG. 5;

FIGS. 7 to 9 are cross-sectional views illustrating first to third inorganic layers in FIG. 6 in detail, respectively;

FIG. 10 is a cross-sectional view illustrating another embodiment of a portion of a display device;

FIG. 11 is a cross-sectional view illustrating another embodiment of a portion of a display device; and

FIGS. 12 to 29 are cross-sectional views sequentially illustrating another embodiment of processes for fabricating of a display device.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it may be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the invention. Similarly, the second element could also be termed the first element.

Hereinafter, embodiments will be described with reference to the accompanying drawings.

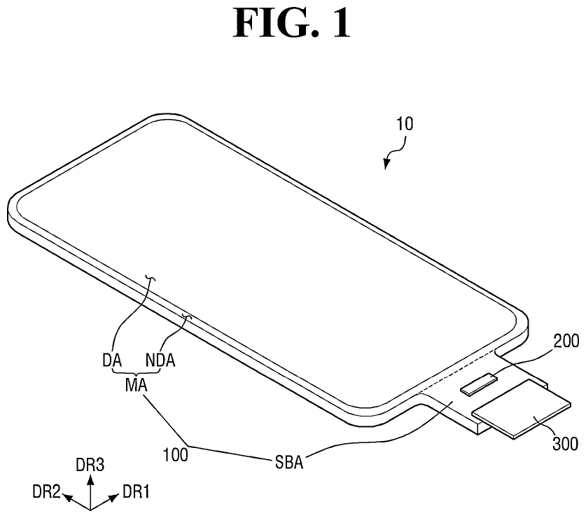

FIG. 1 is a perspective view illustrating an embodiment of a display device.

Referring to FIG. 1, a display device 10 in an embodiment is included in an electronic device and may provide a screen displayed on the electronic device. The electronic device may refer to all electronic devices that provide a display screen. In an embodiment, the electronic device may include televisions, laptop computers, monitors, billboards, Internet of things, mobile phones, smartphones, tablet personal computers (“PCs”), electronic watches, smart glasses, smartwatches, watch phones, head mounted displays, mobile communication terminals, electronic notebooks, electronic books, portable multimedia players (“PMPs”), navigation, game consoles, digital cameras, camcorders, or the like that provide the display screen, for example.

A shape of the display device 10 may be variously changed. In an embodiment, the display device 10 may have a shape similar to a rectangle having short sides in a first direction DR1 and long sides in a second direction DR2, for example. A corner where the short side in the first direction DR1 and the long side in the second direction DR2 meet may be rounded to have a curvature, but is not limited thereto and may also be formed at a right angle. The planar shape of the display device 10 is not limited to the quadrangle, and may be formed similarly to other polygons, circles, or ovals.

The display device 10 may include a display panel 100, a display driver 200, a circuit board 300, and a touch driver 400.

The display panel 100 may include a main area MA and a sub-area SBA.

The main area MA may include a display area DA including pixels displaying an image, and a non-display area NDA disposed around the display area DA. The display area DA may emit light from a plurality of light-emitting areas or a plurality of opening areas. In an embodiment, the display panel 100 may include a pixel circuit including switching elements, a pixel defining layer defining the light-emitting areas or the opening areas, and a self-light-emitting element, for example.

In an embodiment, the self-light-emitting element may include, but is not limited to, at least one of an organic light-emitting diode (“LED”) including an organic light-emitting layer, a quantum dot LED including a quantum dot light-emitting layer, an inorganic LED including an inorganic semiconductor, and a micro LED, for example.

In the display area DA, a plurality of pixels, a plurality of scan lines, a plurality of data lines, and a plurality of power lines may be disposed. Each of the plurality of pixels may be defined as a minimum unit that emits light, and each of the above-described self-emitting elements may be each pixel. The plurality of scan lines may supply scan signals received from a scan driver to the plurality of pixels. The plurality of data lines may supply a data voltage received from the display driver 200 to the plurality of pixels. The plurality of power lines may supply a power voltage received from the display driver 200 to the plurality of pixels.

The non-display area NDA may be an area outside the display area DA. The non-display area NDA may be defined as an edge area of the main area MA of the display panel 100. The non-display area NDA may include a scan driver that supplies scan signals to the scan lines, and fan-out lines that connect the display driver 200 and the display area DA. The sub-area SBA may be an area extending from one side of the main area MA.

The sub-area SBA may include a flexible material that may be bent, folded, rolled, or the like. In an embodiment, when the sub-area SBA is bent, the sub-area SBA may overlap the main area MA in a thickness direction (a third direction DR3), for example. The sub-area SBA may include the display driver 200 and a pad portion connected to the circuit board 300. In another embodiment, the sub-area SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to the power line and may supply a scan control signal to the scan driver. The display driver 200 may be formed as an integrated circuit (“IC”) and disposed (e.g., mounted) on the display panel 100 by a chip on glass (“COG”) method, a chip on plastic (“COP”) method, or an ultrasonic bonding method. In an embodiment, the display driver 200 may be disposed in the sub-area SBA, and may overlap the main area MA in a thickness direction (a third direction DR3) by bending of the sub-area SBA, for example. In another embodiment, the display driver 200 may be disposed (e.g., mounted) on the circuit board 300.

The circuit board 300 may be attached onto the pad portion of the display panel 100 using an anisotropic conductive film (“ACF”). Lead lines of the circuit board 300 may be electrically connected to the pad portion of the display panel 100. The circuit board 300 may be a flexible film such as a flexible printed circuit board, a printed circuit board, or a chip on film.

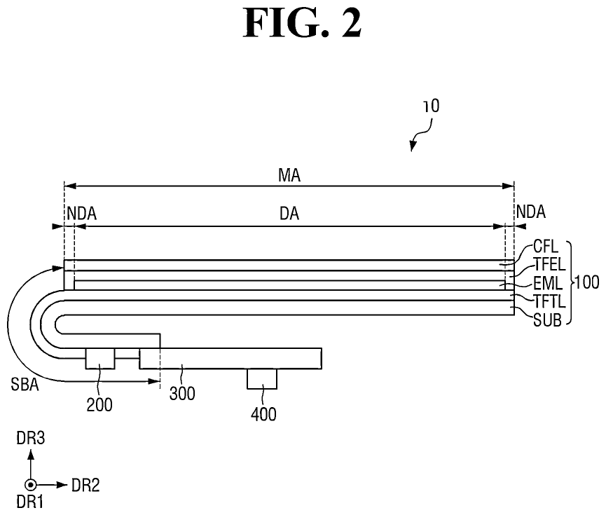

FIG. 2 is a cross-sectional view of the display device of FIG. 1 viewed from a side. Specifically, FIG. 2 relates to a side of the display device in FIG. 1 in a folded state.

Referring to FIG. 2, a display panel 100 may include a substrate SUB, a thin film transistor layer TFTL, a light-emitting element layer EML, a thin film encapsulation layer TFEL, and a color filter layer CFL.

The substrate SUB may be a base substrate or a base member. The substrate SUB may be a flexible substrate that may be bent, folded, rolled, or the like. In an embodiment, the substrate SUB may include a polymer resin such as polyimide PI, for example, but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include scan lines, data lines, power lines, scan control lines, fan-out lines connecting the display driver 200 and the data lines, and lead lines connecting the display driver 200 and the pad portion. Each of the thin film transistors may include a semiconductor area, a source electrode, a drain electrode, and a gate electrode. In an embodiment, when the scan driver is formed on one side of the non-display area NDA of the display panel 100, the scan driver may include thin film transistors, for example.

The thin film transistor layer TFTL may be disposed in the display area DA, the non-display area NDA, and the sub-area SBA. The thin film transistors, the scan lines, the data lines, and the power lines of each of the pixels of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light-emitting element layer EML may be disposed on the thin film transistor layer TFTL. The light-emitting element layer EML may include a plurality of light-emitting elements including a first electrode, a second electrode, and a light-emitting layer to emit light, and a pixel defining layer defining pixels. The plurality of light-emitting elements of the light-emitting element layer EML may be disposed in the display area DA.

In an embodiment, the light-emitting layer may be an organic light-emitting layer including an organic material. The light-emitting layer may include a hole transporting layer, an organic light-emitting layer, and an electron transporting layer. When the first electrode receives a voltage through the thin film transistor of the thin film transistor layer TFTL and the second electrode receives a cathode voltage, holes and electrons may move to the organic light-emitting layer through the hole transporting layer and the electron transporting layer, respectively, and may be combined with each other in the organic light-emitting layer to emit light.

In another embodiment, the light-emitting element may include a quantum dot light-emitting diode including a quantum dot light-emitting layer, an inorganic light-emitting diode including an inorganic semiconductor, or a micro light-emitting diode.

The thin film encapsulation layer TFEL may cover an upper surface and side surfaces of the light-emitting element layer EML, and may protect the light-emitting element layer EML. The thin film encapsulation layer TFEL may include at least one inorganic film and at least one organic film for encapsulating the light-emitting element layer EML.

The color filter layer CFL may be disposed on the thin film encapsulation layer TFEL. The color filter layer CFL may include a plurality of color filters corresponding to each of the plurality of light-emitting areas. Each of the color filters may selectively transmit light of a predetermined wavelength and block or absorb light of a different wavelength. The color filter layer CFL may absorb a portion of light introduced from the outside of the display device 10 to reduce reflected light caused by external light. Therefore, the color filter layer CFL may prevent color distortion caused by reflection of external light.

As the color filter layer CFL is directly disposed on the thin film encapsulation layer TFEL, a separate substrate for the color filter layer CFL may not be desired in the display device 10. Therefore, the display device 10 may have a relatively small thickness.

In some embodiments, the display device 10 may further include an optical device. The optical device may emit or receive light in infrared, ultraviolet, and visible light bands. In an embodiment, the optical device may be an optical sensor that senses light incident on the display device 10, such as a proximity sensor, an illumination sensor, a camera sensor, a fingerprint sensor, or an image sensor, for example.

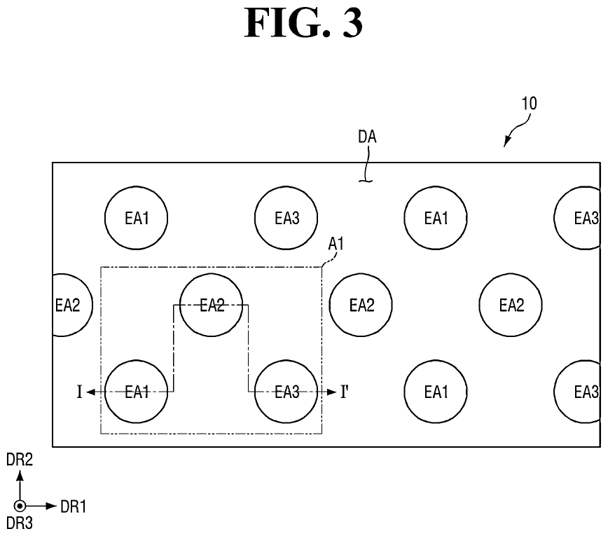

FIG. 3 is a plan view illustrating an embodiment of a portion of the display device. FIG. 3 is a plan view illustrating an arrangement of light-emitting areas EA1, EA2, and EA3 in the display area DA of the display device 10.

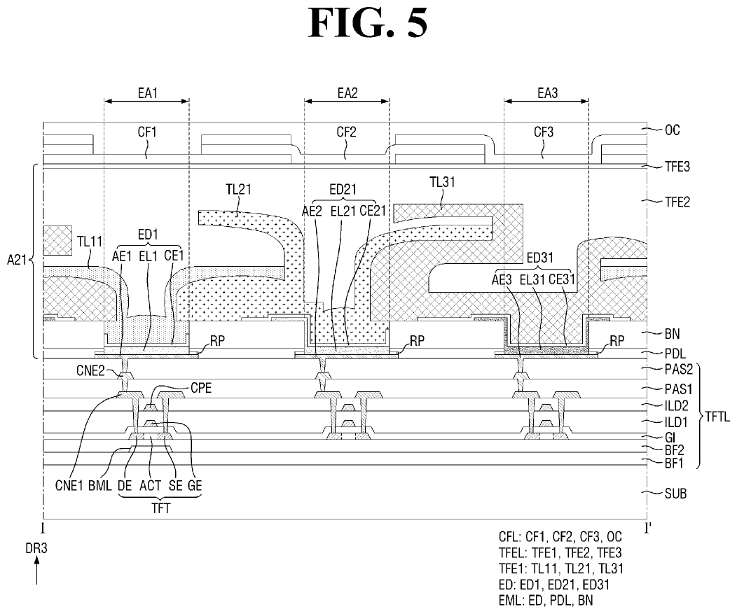

Referring to FIG. 3, the display device 10 may include a plurality of light-emitting areas EA1, EA2, and EA3 disposed in the display area DA. The light-emitting areas EA1, EA2, and EA3 may include a first light-emitting area EA1, a second light-emitting area EA2, and a third light-emitting area EA3 that emit light of different colors. The first to third light-emitting areas EA1, EA2, and EA3 may emit red, green, or blue light, respectively, and the color of light emitted from each of the light-emitting areas EA1, EA2, and EA3 may be different depending on the types of light-emitting elements (‘ED1’, ‘ED21’, and ‘ED31’ in FIG. 5) to be described later. In an embodiment, the first light-emitting area EA1 may emit first light of a red color, the second light-emitting area EA2 may emit second light of a green color, and the third light-emitting area EA3 may emit third light of a blue color. However, the disclosure is not limited thereto.

The plurality of light-emitting areas EA1, EA2, and EA3 may be disposed in a Pentile™ type, e.g., a diamond Pentile™ type. In an embodiment, the first light-emitting area EA1 and the third light-emitting area EA3 may be spaced apart from each other in the first direction DR1, and may be alternately disposed in the first direction DR1 and the second direction DR2, for example. The second light-emitting area EA2 may be spaced apart from another adjacent second light-emitting area EA2 in the first direction DR1 and the second direction DR2. The second light-emitting area EA2 and the first light-emitting area EA1, or the second light-emitting area EA2 and the third light-emitting area EA3 may be alternately disposed along any direction in a plane formed by the first direction DR1 and the second direction DR2.

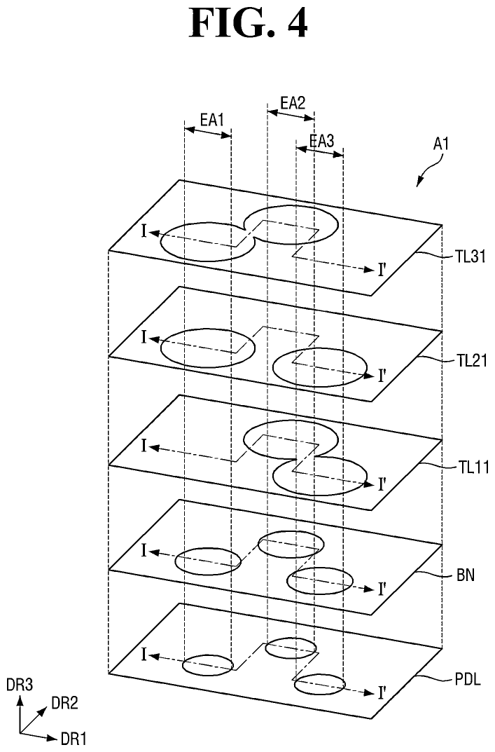

The first to third light-emitting areas EA1, EA2, and EA3 may be defined by a pixel defining layer (‘PDL’ in FIG. 4) to be described later.

In the display device 10, the first light-emitting area EA1, the second light-emitting area EA2, and the third light-emitting area EA3 disposed adjacent to each other may form one pixel group. Referring to FIG. 3, area A1 indicates one pixel group. FIG. 4 is an exploded perspective view illustrating a stacking of a light-emitting element layer EML and a lower inorganic encapsulation layer TFE1 in area A1 of FIG. 3.

Referring to FIG. 4, the pixel defining layer PDL may define the first to third light-emitting areas EA1, EA2, and EA3. A bank BN and first to third inorganic layers TL11, TL21, and TL31 are sequentially stacked on the pixel defining layer PDL, and portions corresponding to the light-emitting areas are exposed. Exposed areas of the bank BN may overlap the first to third light-emitting areas EA1, EA2, and EA3. An exposed area of the first inorganic layer TL11 may overlap an entirety of the second and third light-emitting areas EA2 and EA3. An exposed area of the second inorganic layer TL21 may overlap an entirety of the first and third light-emitting areas EA1 and EA3. An exposed area of the third inorganic layer TL31 may overlap an entirety of the first and second light-emitting areas EA1 and EA2. In FIG. 4, the light-emitting elements, the transistor layers, etc. are omitted.

FIG. 5 is a cross-sectional view illustrating an embodiment of a portion of the display device. Specifically, FIG. 5 is a cross-sectional view of portion I-I′ of FIGS. 3 and 4. Referring to FIG. 5, the thin film transistor layer TFTL, the light-emitting element layer EML, the thin film encapsulation layer TFEL, and the color filter layer CFL may be sequentially stacked on the substrate SUB.

The thin film transistor layer TFTL may include a first buffer layer BF1, a lower metal layer BML, a second buffer layer BF2, a thin film transistor TFT, a gate insulating layer GI, a first inter-insulating layer ILD1, a capacitor electrode CPE, a second inter-insulating layer ILD2, a first connection electrode CNE1, a first passivation layer PAS1, a second connection electrode CNE2, and a second passivation layer PAS2.

The first buffer layer BF1 may be disposed on the substrate SUB. The first buffer layer BF1 may include an inorganic film capable of preventing permeation of air or moisture. In an embodiment, the first buffer layer BF1 may include a plurality of inorganic films alternately stacked, for example.

The lower metal layer BML may be disposed on the first buffer layer BF1. In an embodiment, the lower metal layer BML may include or consist of a single layer or a multi-layer including or consisting of any one of molybdenum (Mo), aluminum (Al), chromium (Cr), gold (Au), titanium (Ti), nickel (Ni), neodymium (Nd), and copper (Cu), or any alloys thereof, for example.

The second buffer layer BF2 may cover the first buffer layer BF1 and the lower metal layer BML. The second buffer layer BF2 may include an inorganic film capable of preventing permeation of air or moisture. In an embodiment, the second buffer layer BF2 may include a plurality of inorganic films alternately stacked, for example.

The thin film transistor TFT may be disposed on the second buffer layer BF2, and may constitute a pixel circuit of each of the plurality of pixels. In an embodiment, the thin film transistor TFT may be a driving transistor or a switching transistor of the pixel circuit, for example. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the lower metal layer BML and the gate electrode GE in the thickness direction DR3, and may be insulated from the gate electrode GE by the gate insulating layer GI. In a portion of the semiconductor layer ACT, a material of the semiconductor layer ACT may become a conductor to form the source electrode SE and the drain electrode DE.

The gate electrode GE may be disposed on the gate insulating layer GI. The gate electrode GE may overlap the semiconductor layer ACT in the thickness direction DR3, with the gate insulating layer GI interposed therebetween.

The gate insulating layer GI may be disposed on the semiconductor layer ACT. In an embodiment, the gate insulating layer GI may cover the semiconductor layer ACT and the second buffer layer BF2, and may insulate the semiconductor layer ACT and the gate electrode GE from each other, for example. The gate insulating layer GI may define a contact hole through which the first connection electrode CNE1 penetrates.

The first inter-insulating layer ILD1 may cover the gate electrode GE and the gate insulating layer GI. The first inter-insulating layer ILD1 may define a contact hole through which the first connection electrode CNE1 penetrates. The contact hole of the first inter-insulating layer ILD1 may be extended to the contact hole of the gate insulating layer GI and a contact hole of the second inter-insulating layer ILD2.

The capacitor electrode CPE may be disposed on the first inter-insulating layer ILD1. The capacitor electrode CPE may overlap the gate electrode GE in the thickness direction DR3. The capacitor electrode CPE and the gate electrode GE may form a capacitance.

The second inter-insulating layer ILD2 may cover the capacitor electrode CPE and the first inter-insulating layer ILD1. The second inter-insulating layer ILD2 may define a contact hole through which the first connection electrode CNE1 penetrates. The contact hole of the second inter-insulating layer ILD2 may be extended to the contact hole of the first inter-insulating layer ILD1 and the contact hole of the gate insulating layer GI.

The first connection electrode CNE1 may be disposed on the second inter-insulating layer ILD2. The first connection electrode CNE1 may electrically connect the drain electrode DE of the thin film transistor TFT and the second connection electrode CNE2 to each other. The first connection electrode CNE1 may be inserted into the contact holes defined in the second inter-insulating layer ILD2, the first inter-insulating layer ILD1, and the gate insulating layer GI to contact the drain electrode DE of the thin film transistor TFT.

The first passivation layer PAS1 may cover the first connection electrode CNE1 and the second inter-insulating layer ILD2. The first passivation layer PAS1 may protect the thin film transistor TFT. The first passivation layer PAS1 may define a contact hole through which the second connection electrode CNE2 penetrates.

The second connection electrode CNE2 may be disposed on the first passivation layer PAS1. The second connection electrode CNE2 may electrically connect the first connection electrode CNE1 and pixel electrodes AE1, AE2, and AE3 of the light-emitting element ED to each other. The second connection electrode CNE2 may be inserted into the contact hole defined in the first passivation layer PAS1 and contact the first connection electrode CNE1.

The second passivation layer PAS2 may cover the second connection electrode CNE2 and the first passivation layer PAS1. The second passivation layer PAS2 may include contact holes through which the pixel electrodes AE1, AE2, and AE3 of the light-emitting element ED penetrate.

The light-emitting element layer EML may be disposed on the thin film transistor layer TFTL. The light-emitting element layer EML may include a light-emitting element ED, a pixel defining layer PDL, a capping layer, and a bank BN. The light-emitting element ED may include pixel electrodes AE1, AE2, and AE3, light-emitting layers EL1, EL21, and EL31, and common electrodes CE1, CE21, and CE31.

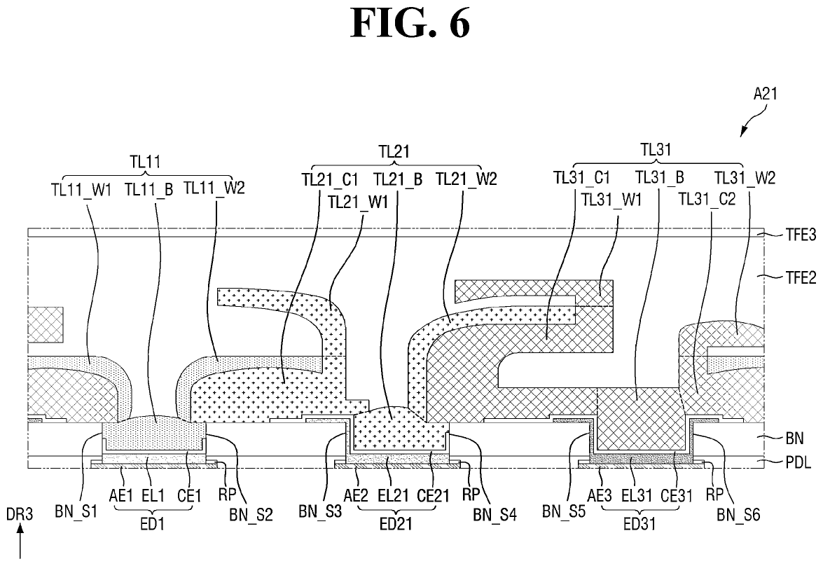

FIG. 6 is an enlarged view illustrating the light-emitting element layer EML and the thin film encapsulation layer TFTL of FIG. 5, specifically area A21.

Referring to FIG. 6 in addition to FIG. 5, the display device 10 may include a plurality of light-emitting areas EA1, EA2, and EA3 disposed in the display area DA. The light-emitting areas EA1, EA2, and EA3 may include an area where light is emitted from the light-emitting elements ED1, ED21, and ED31 including the pixel electrodes AE1, AE2, and AE3, the light-emitting layers EL1, EL21, and EL31, and the common electrode CE1, CE21, and CE31 and passes through the color filter layer CFL in the third direction DR3. Boundaries of the light-emitting areas EA1, EA2, and EA3 may be defined by the pixel defining layer PDL. The light-emitting areas EA1, EA2, and EA3 may include a first light-emitting area EA1, a second light-emitting area EA2, and a third light-emitting area EA3 that are spaced apart from each other and emit light of the same or different colors.

In an embodiment, the areas or sizes of the first to third light-emitting areas EA1, EA2, and EA3 may be the same as each other. In an embodiment, in the display device 10, the first light-emitting area EA1, the second light-emitting area EA2, and the third light-emitting area EA3 may have the same area, for example. However, the disclosure is not limited thereto. In the display device 10, the areas or sizes of the first to third light-emitting areas EA1, EA2, and EA3 may be different from each other. In an embodiment, the area of the second light-emitting area EA2 may be smaller than the areas of the first light-emitting area EA1 and the third light-emitting area EA3, and the area of the third light-emitting area EA3 may be greater than the area of the first light-emitting area EA1, for example. Intensities of light emitted from the light-emitting areas EA1, EA2, and EA3 may vary depending on the areas of the light-emitting areas EA1, EA2, and EA3, and a color of a screen displayed on the display device 10 may be controlled by adjusting the areas of the light-emitting areas EA1, EA2, and EA3. The areas of the light-emitting areas EA1, EA2, and EA3 are illustrated to be the same in the embodiments of FIGS. 3 to 5, but are not limited thereto.

In the display device 10, one first light-emitting area EA1, one second light-emitting area EA2, and one third light-emitting area EA3 disposed adjacent to each other may form one pixel group. One pixel group may express a white gradation by including the light-emitting areas EA1, EA2, and EA3 emitting light of different colors. However, the disclosure is not limited thereto, and a combination of the light-emitting areas EA1, EA2, and EA3 constituting one pixel group may be variously modified according to the arrangement of the light-emitting areas EA1, EA2, and EA3, and the colors of the light emitted therefrom.

The display device 10 may include a plurality of light-emitting elements ED1, ED21, and ED31 disposed in different light-emitting areas EA1, EA2, and EA3. The light-emitting elements ED1, ED21, and ED31 may include a first light-emitting element ED1 disposed in the first light-emitting area EA1, a second light-emitting element ED21 disposed in the second light-emitting area EA2, and a third light-emitting element ED31 disposed in the third light-emitting area EA3.

Each of the light-emitting elements ED1, ED21, and ED31 includes pixel electrodes (also referred to as anode electrodes) AE1, AE2, and AE3, light-emitting layers EL1, EL21, and EL31, and common electrodes CE1, CE21, and CE31, and the light-emitting elements ED1, ED21, and ED31 disposed in different light-emitting areas EA1, EA2, and EA3 may emit light of different colors depending on the material of the light-emitting layers EL1, EL21, and EL31. In an embodiment, the first light-emitting element ED1 disposed in the first light-emitting area EA1 may emit first light of a red color having a peak wavelength in the range of 610 nanometers (nm) to 650 nm, the second light-emitting element ED21 disposed in the second light-emitting area EA2 may emit second light of a green color having a peak wavelength in the range of 510 nm to 550 nm, and the third light-emitting element ED31 disposed in the third light-emitting area EA3 may emit third light of a blue color having a peak wavelength in the range of 440 nm to 480 nm, for example. The first to third light-emitting areas EA1, EA2, and EA3 constituting one pixel may express a white gradation by including the light-emitting elements ED1, ED21, and ED31 that emit light of different colors. In an alternative embodiment, the light-emitting layers EL1, EL21, and EL31 may include two or more materials that emit light of different colors, so that one light-emitting layer may emit mixed light. In an embodiment, the light-emitting layers EL1, EL21, and EL31 may emit yellow light by including a material that emits red light and a material that emits green light, or may emit white light by including a material that emits red light, a material that emits green light, and a material that emits blue light, for example.

The pixel electrodes AE1, AE2, and AE3 may be disposed on the second passivation layer PAS2. The pixel electrodes AE1, AE2, and AE3 may be respectively disposed in the plurality of light-emitting areas EA1, EA2, and EA3. The pixel electrodes AE1, AE2, and AE3 may include a first pixel electrode AE1 disposed in the first light-emitting area EA1, a second pixel electrode AE2 disposed in the second light-emitting area EA2, and a third pixel electrode AE3 disposed in the third light-emitting area EA3. The first pixel electrode AE1, the second pixel electrode AE2, and the third pixel electrode AE3 may be spaced apart from each other on the second passivation layer PAS2.

The pixel electrodes AE1, AE2, and AE3 may be electrically connected to the drain electrode DE of the thin film transistor TFT through the first and second connection electrodes CNE1 and CNE2. Edges of the pixel electrodes AE1, AE2, and AE3 spaced apart from each other may be covered by the pixel defining layer PDL, so that the first to third pixel electrodes AE1, AE2, and AE3 may be insulated from each other.

The pixel electrodes AE1, AE2, and AE3 may include a transparent electrode material and/or a conductive metal material. The metal material may be one or more of silver (Ag), copper (Cu), aluminum (Al), nickel (Ni), lanthanum (La), titanium (Ti), and titanium nitride (TiN). The transparent electrode material may be one or more of Indium Tin Oxide (“ITO”), Indium Zinc Oxide (“IZO”), and Indium Tin Zinc Oxide (“ITZO”). The pixel electrodes AE1, AE2, and AE3 may be a multi-layer structure of the transparent electrode material and the conductive metal material.

The pixel defining layer PDL may be disposed on the second passivation layer PAS2, a residual pattern RP, and the pixel electrodes AE1, AE2, and AE3. The pixel defining layer PDL is entirely disposed on the second passivation layer PAS2, and may cover side surfaces of the pixel electrodes AE1, AE2, and AE3 and the residual pattern RP, thereby exposing a portion of upper surface of the pixel electrodes AE1, AE2, and AE3. In an embodiment, the pixel defining layer PDL may expose the first pixel electrode AE1 in the first light-emitting area EA1, and the first light-emitting layer EL1 may be directly disposed on the first pixel electrode AE1, for example.

The pixel defining layer PDL may include an inorganic insulating material. The pixel defining layer PDL may include at least one of a silicon nitride layer, a silicon oxynitride layer, a silicon oxide layer, a titanium oxide layer, an aluminum oxide layer, a tantalum oxide, a hafnium oxide, zinc oxide, and an amorphous silicon layer, but is not limited thereto.

The pixel defining layer PDL may have a side surface that is aligned with a side surface of a bank BN, which will be described later, or protrudes. The side surface of the pixel defining layer PDL, which is a boundary defining the light-emitting areas EA1, EA2, and EA3, may overlap the pixel electrodes AE1, AE2, and AE3. It is illustrated in the drawings that the side surface of the pixel defining layer PDL is aligned with the side surface of the bank BN, but the side surface of the pixel defining layer PDL may protrude more than the side surface of the bank BN toward the center of the pixel electrodes AE1, AE2, and AE3.

In an embodiment, the pixel defining layer PDL may be disposed on the pixel electrodes AE1, AE2, and AE3, and may be spaced apart from upper surfaces of the pixel electrodes AE1, AE2, and AE3. The pixel defining layer PDL may partially overlap the upper surfaces of the pixel electrodes AE1, AE2, and AE3 in the thickness direction DR3 of the substrate SUB and may not be in direct contact with the upper surfaces of the pixel electrodes AE1, AE2, and AE3, and the residual pattern RP may be disposed between the pixel defining layer PDL and the pixel electrodes AE1, AE2, and AE3. However, the pixel defining layer PDL may be in direct contact with the side surfaces of the pixel electrodes AE1, AE2, and AE3.

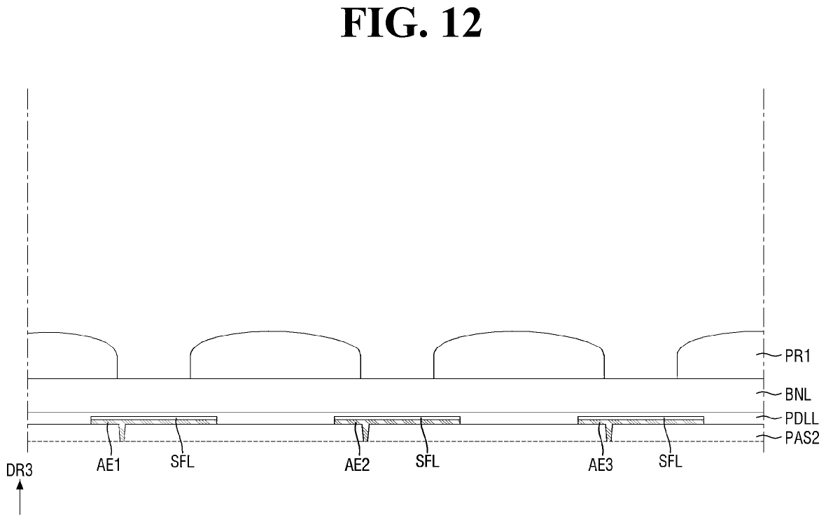

The residual pattern RP may be disposed on the edge of each of the pixel electrodes AE1, AE2, and AE3. The pixel defining layer PDL may not be in direct contact with the upper surfaces of the pixel electrodes AE1, AE2, and AE3 due to the residual pattern RP. The residual pattern RP may be formed by removing a portion of a sacrificial layer (“SFL” in FIG. 12) disposed on the pixel electrodes AE1, AE2, and AE3 during the process of fabricating the display device 10. The residual pattern RP may include a metal, an oxide semiconductor, or a transparent conductive oxide (“TCO”).

The bank BN may be disposed on the pixel defining layer PDL. The bank BN may have a single-layer or multi-layer structure. In an embodiment, the bank BN may be a single film of metal or metal alloy. The material of the bank BN may be a highly conductive metal such as aluminum (Al), titanium (Ti), or molybdenum (Mo), or any alloys thereof.

The bank BN may define openings overlapping the light-emitting areas EA1, EA2, and EA3, and may expose the pixel electrodes AE1, AE2, and AE3. The bank BN may include side surfaces in the opening. The bank BN may include a first side surface BN_S1 and a second side surface BN_S2 that overlap or are adjacent to the first light-emitting area EA1. The first side surface BN_S1 and the second side surface BN_S2 of the bank BN may be different side surfaces or sides disposed within the same opening, and may be surfaces facing each other. The bank BN may include a third side surface BN_S3 and a fourth side surface BN_S4 that overlap or are adjacent to the second light-emitting area EA2. The third side surface BN_S3 and the fourth side surface BN_S4 of the bank BN may be different side surfaces or sides disposed within the same opening, and may be surfaces facing each other. The bank BN may include a fifth side surface BN_S5 and a sixth side surface BN_S6 that overlap or are adjacent to the third light-emitting area EA3. The fifth side surface BN_S5 and the sixth side surface BN_S6 of the bank BN may be different side surfaces or sides disposed within the same opening, and may be surfaces facing each other.

The light-emitting layers EL1, EL21, and EL31 may be disposed on the pixel electrodes AE1, AE2, and AE3. The light-emitting layers EL1, EL21, and EL31 may be organic light-emitting layers including or consisting of organic materials, and may be formed on the pixel electrodes AE1, AE2, and AE3 through a deposition process. The light-emitting layers EL1, EL21, and EL31 may have a multi-layer structure, and a hole injection material, a hole transporting material, a light-emitting material, an electron transporting material, or/and an electron injection material may each constitute a layer. When the thin film transistor TFT applies a predetermined voltage to the pixel electrodes AE1, AE2, and AE3 of the light-emitting elements ED1, ED21, and ED31, and the common electrodes CE1, CE21, and CE31 of the light-emitting elements ED1, ED21, and ED31 receive a common voltage or a cathode voltage, holes and electrons are each injected and transported, and the holes and electrons may be combined with each other in the light-emitting layers EL1, EL21, and EL31 to emit light.

The light-emitting layers EL1, EL21, and EL31 may include a first light-emitting layer EL1, a second light-emitting layer EL21, and a third light-emitting layer EL31 disposed in different light-emitting areas EA1, EA2, and EA3. The first light-emitting layer EL1 may be disposed on the first pixel electrode AE1 in the first light-emitting area EA1, the second light-emitting layer EL21 may be disposed on the second pixel electrode AE2 in the second light-emitting area EA2, and the third light-emitting layer EL31 may be disposed on the third pixel electrode AE3 in the third light-emitting area EA3. The first to third light-emitting layers EL1, EL21, and EL31 may be spaced apart from each other. Each of the plurality of light-emitting layers EL1, EL21, and EL31 may emit different colors, or one light-emitting layer EL1, EL21, or EL31 may emit mixed light. In an embodiment, the first light-emitting layer EL1 may emit red light, the second light-emitting layer EL21 may emit green light, and the third light-emitting layer EL31 may emit blue light. In another embodiment, the first light-emitting layer EL1 may emit yellow light, which is mixed light of red light and green light, and the second light-emitting layer EL21 may emit blue light. In another embodiment, the first light-emitting layer EL1 may emit white light, which is mixed light of red light, green light, and blue light.

The first to third light-emitting layers EL1, EL21, and EL31 are each disposed to overlap the opening of the bank BN, but cross-sectional shapes thereof may be different from each other. Referring to FIGS. 5 and 6, the first light-emitting layer EL1 may be disposed only within the opening of the bank BN, and one end and an opposite end of the first light-emitting layer EL1 may be disposed on the first side surface BN_S1 and the second side surface BN_S2 of the bank BN1. A portion of the second light-emitting layer EL21 may be disposed within the opening of the bank BN, and another portion of the second light-emitting layer EL21 may be disposed on the upper surface of the bank BN. One end of the second light-emitting layer EL21 may be disposed on the upper surface of the bank BN, and an opposite end thereof may be disposed on the fourth side surface BN_S4 of the bank BN. A portion of the third light-emitting layer EL31 may be disposed within the opening of the bank BN, and another portion of the third light-emitting layer EL31 may be disposed on the upper surface of the bank BN. One end and an opposite end of the third light-emitting layer EL31 may be disposed on the upper surface of the bank BN. In a cross-section of the substrate SUB cut in the thickness direction DR3, the first light-emitting layer EL1 may include a U-shaped or rod-shaped cross section, the second light-emitting layer EL21 may include a U-shaped cross section with one end bent (a U shape including one wing), and the third light-emitting layer EL31 may include a U-shaped cross section with one end and an opposite end bent (a U shape including two wings).

The common electrodes CE1, CE21, and CE31 may be disposed on the light-emitting layers EL1, EL21, and EL31. The common electrodes (also referred to as cathode electrodes) CE1, CE21, and CE31 include a transparent conductive material so that the light generated in the light-emitting layers EL1, EL21, and EL31 may be emitted. The common electrodes CE1, CE21, and CE31 may receive a common voltage or a relatively low potential voltage. When the pixel electrodes AE1, AE2, and AE3 receive a voltage corresponding to the data voltage and the common electrodes CE1, CE21, and CE31 receive a relatively low potential voltage, the light-emitting layers EL1, EL21, and EL31 may emit light as a potential difference is formed between the pixel electrodes AE1, AE2, and AE3 and the common electrodes CE1, CE21, and CE31.

The common electrodes CE1, CE21, and CE31 may include a first common electrode CE1, a second common electrode CE21, and a third common electrode CE31 disposed in different light-emitting areas EA1, EA2, and EA3. The first common electrode CE1 may be disposed on the first light-emitting layer EL1 in the first light-emitting area EA1, the second common electrode CE21 may be disposed on the second light-emitting layer EL21 in the second light-emitting area EA2, and the third common electrode CE31 may be disposed on the third light-emitting layer EL31 in the third light-emitting area EA3. The first to third common electrodes CE1, CE21, and CE31 may be spaced apart from each other.

The first to third common electrodes CE1, CE21, and CE31 are each disposed to overlap the opening of the bank BN, but cross-sectional shapes thereof may be different from each other. In a cross-section of the substrate SUB cut in the thickness direction DR3, the first common electrode CE1 may include a U-shaped cross section, the second common electrode CE21 may include a U-shaped cross section with one end bent (a U shape including one wing), and the third common electrode CE31 may include a U-shaped cross section with one end and an opposite end bent (a U shape including two wings).

The first to third common electrodes CE1, CE21, and CE31 may have different widths. In the specification, unless explicitly defined, the width may be a distance between one end and an opposite end measured in an extension direction of the substrate SUB. In an embodiment, a width d1 of the first common electrode CE1 may be smaller than a width d21 of the second common electrode CE21, and the width d21 of the second common electrode CE21 may be smaller than a width d31 of the third common electrode CE31.

The first common electrode CE1 may be disposed only within the opening of the bank BN. The first common electrode CE1 may be disposed on at least a portion of the first side surface BN_S1 of the bank BN and at least a portion of the second side surface BN_S2 of the bank BN. One end and an opposite end of the first common electrode CE1 may be disposed on the first side surface BN_S1 and the second side surface BN_S2 of the bank BN1. The first common electrode CE1 may not be disposed on the upper surface of the bank BN. The heights of one end and an opposite end of the first common electrode CE1 may be the same as each other.

A portion of the second common electrode CE21 may be disposed within the opening of the bank BN, and another portion of the second common electrode CE21 may be disposed on the upper surface of the bank BN. The second common electrode CE21 may be disposed on an entirety of the third side surface BN_S3 of the bank BN, at least a portion of the fourth side surface BN_S4 of the bank BN, and at least a portion of the upper surface of the bank BN. One end of the second common electrode CE21 may be disposed on the upper surface of the bank BN, and an opposite end thereof may be disposed on the fourth side surface BN_S4 of the bank BN. The wing portion of the second common electrode CE21 may be disposed on the upper surface of the bank BN disposed between the first light-emitting area EA1 and the second light-emitting area EA2. A height of one end of the second common electrode CE21 may be greater than a height of an opposite end of the second common electrode CE21.

A portion of the third common electrode CE31 may be disposed within the opening of the bank BN, and another portion of the third common electrode CE31 may be disposed on the upper surface of the bank BN. The third common electrode CE31 may be disposed on an entirety of the fifth side surface BN_S5 of the bank BN, an entirety of the sixth side surface BN_S6 of the bank BN, and at least a portion of the upper surface of the bank BN. One end and an opposite end of the third common electrode CE31 may be disposed on the upper surface of the bank BN. A first wing portion of the third common electrode CE31 may be disposed on the upper surface of the bank BN disposed between the second light-emitting area EA2 and the third light-emitting area EA3, and a second wing portion of the third common electrode CE31 may be disposed on the upper surface of the bank BN disposed between the third light-emitting area EA3 and the first light-emitting area EA1. The heights of one end and an opposite end of the third common electrode CE31 may be the same as each other.

In an embodiment, the width d1 of the first common electrode CE1 may be smaller than a width 11 of the first pixel electrode AE1, the width d21 of the second common electrode CE21 may be greater than a width 12 of the second pixel electrode AE2, and the width d31 of the third common electrode CE31 may be greater than a width 13 of the third pixel electrode AE3.

In an embodiment, a width (d311+d312) of the third common electrode CE31 disposed on the upper surface of the bank BN may be different from a width d211 of the second common electrode disposed on the upper surface of the bank BN. The width (d311+d312) of the third common electrode CE31 disposed on the upper surface of the bank BN may be greater than the width d211 of the second common electrode disposed on the upper surface of the bank BN. A width d311 of the first wing portion of the third common electrode CE31 may be greater than the width d211 of the wing portion of the second common electrode CE21.

The first to third common electrodes CE1, CE21, and CE31 may contact the bank BN, and the bank BN may include a metal material. The common electrodes CE1, CE21, and CE31 spaced apart from each other may be electrically connected through the bank BN. Areas where the first to third common electrodes CE1, CE21, and CE31 are each in contact with the bank BN may be different. The contact area between the first common electrode CE1 and the bank BN may be smaller than the contact area between the second common electrode CE21 and the bank BN, and the contact area between the second common electrode CE21 and the bank BN may be smaller than the contact area between the third common electrode CE31 and the bank BN.

A capping layer (not illustrated) may be optionally disposed on the common electrodes CE1, CE21, and CE31. The capping layer may include an organic or inorganic insulating material and cover the patterns disposed on the light-emitting elements ED1, ED21, and ED31. The capping layer may prevent the light-emitting elements ED1, ED21, and ED31 from being damaged by external air. In an embodiment, the capping layer may include an organic material such as α-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The thin film encapsulation layer TFEL may be disposed on the light-emitting elements ED1, ED21, and ED31 and the bank BN. The thin film encapsulation layer TFEL may include at least one inorganic film to prevent oxygen or moisture from permeating into the light-emitting element layer EML. The thin film encapsulation layer TFEL may include at least one organic film to protect the light-emitting element layer EML from foreign substances such as dust.

In an embodiment, the thin film encapsulation layer TFEL may include a lower inorganic encapsulation layer TFE1, an organic encapsulation layer TFE2, and an upper inorganic encapsulation layer TFE3 that are sequentially stacked

Each of the lower inorganic encapsulation layer TFE1 and the upper inorganic encapsulation layer TFE3 may include one or more inorganic insulating materials. The inorganic insulating material may be any one of silicon oxide, silicon nitride, and silicon oxynitride, e.g., aluminum oxide, titanium oxide, tantalum oxide, hafnium oxide, zinc oxide, silicon oxide, silicon nitride, and/or silicon oxynitride.

The organic encapsulation layer TFE2 may include a polymer-based material. In an embodiment, the polymer-based material may include an acrylic resin, an epoxy-based resin, polyimide, polyethylene, or the like. In an embodiment, the organic encapsulation layer TFE2 may include an acrylic resin, e.g., polymethyl methacrylate or polyacrylic acid. The organic encapsulation layer TFE2 may be formed by curing a monomer or applying a polymer.

The lower inorganic encapsulation layer TFE1 may be disposed on the light-emitting elements ED1, ED21, and ED31 and the bank BN. The lower inorganic encapsulation layer TFE1 may include a first inorganic layer TL11, a second inorganic layer TL21, and a third inorganic layer TL31 disposed to respectively correspond to the different light-emitting areas EA1, EA2, and EA3. The first inorganic layer TL11, the second inorganic layer TL21, and the third inorganic layer TL31 may each include an inorganic insulating material to cover the light-emitting elements ED1, ED21, and ED31.

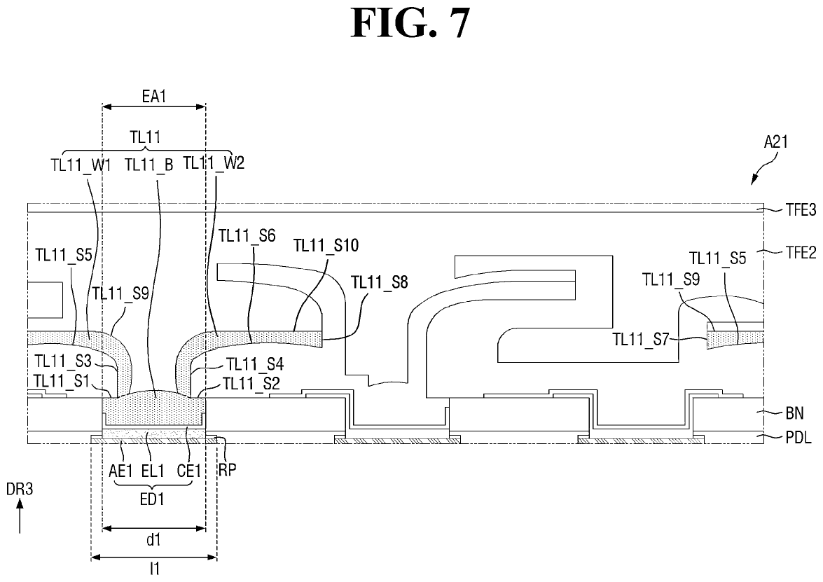

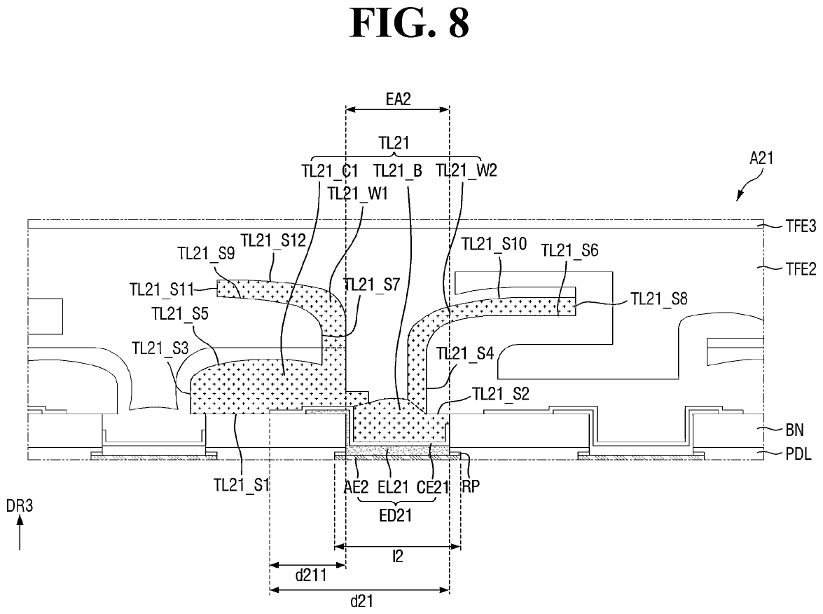

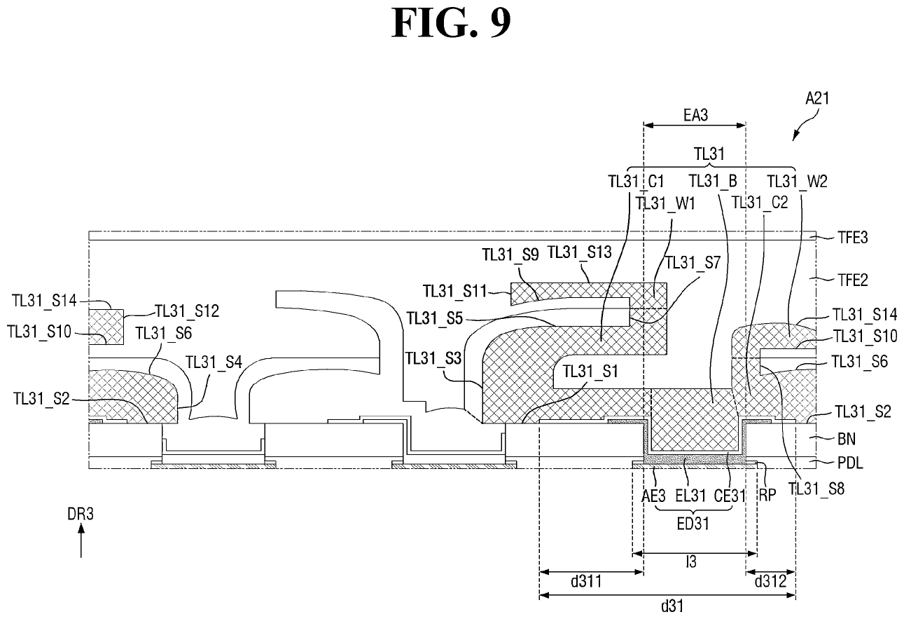

FIGS. 7 to 9 are cross-sectional views illustrating the first to third inorganic layers TL11, TL21, and TL31 of FIG. 6 in detail, respectively.

The lower inorganic encapsulation layer (TFE1: TL11, TL21, TL31) may be formed through chemical vapor deposition (“CVD”), and may be formed along the steps of the deposited layer because of having excellent step coverage. In an embodiment, the second inorganic layer TL21 may also be formed in a space between the upper surface of the bank BN and the first inorganic layer TL11, and may also be formed on a lower surface TL11_S6 of the first inorganic layer TL11, which faces the upper surface of the bank BN, for example.

The first inorganic layer TL11 may include a body portion TL11_B, a first wing portion TL11_W1, and a second wing portion TL11_W2. The body portion TL11_B of the first inorganic layer TL11 may be disposed on the first common electrode CE1 and may overlap the opening of the bank BN and the first light-emitting area EA1. The wing portions TL11_W1 and TL11_W2 of the first inorganic layer TL11, which are portions protruding from the body portion TL11_B, may be disposed on the bank BN and spaced apart from the upper surface of the bank BN. The first wing portion TL11_W1 of the first inorganic layer TL11 may be disposed on the bank between the first light-emitting area EA1 and the third light-emitting area EA3, and the second wing portion TL11_W2 of the first inorganic layer TL11 may be disposed on the bank between the first light-emitting area EA1 and the second light-emitting area EA2.

The second inorganic layer TL21 may include a body portion TL21_B, a connection portion TL21_C1, a first wing portion TL21_W1, and a second wing portion TL21_W2. The body portion TL21_B of the second inorganic layer TL21 may be disposed on the second common electrode CE21 and may overlap the opening of the bank BN and the second light-emitting area EA2. The connection portion TL21_C1 of the second inorganic layer TL21, which is a portion that connects the body portion TL21_B and the first wing portion TL21_W1, may be disposed in a space between the second wing portion TL11_W2 of the first inorganic layer TL11 and the bank BN. The first wing portion TL21_W1 of the second inorganic layer TL21, which is a portion protruding from the connection portion TL21_C1, may be disposed on the second wing portion TL11_W2 of the first inorganic layer TL11 and may be spaced apart from an upper surface TL11_S10 of the second wing portion TL11_W2 of the first inorganic layer TL11. The second wing portion TL21_W2 of the second inorganic layer TL21, which is a portion protruding from the body portion TL21_B, may be disposed on the bank BN between the second light-emitting area EA2 and the third light-emitting area EA3 and may be spaced apart from the upper surface of the bank BN.

The third inorganic layer TL31 may include a body portion TL31_B, a first connection portion TL31_C1, a second connection portion TL31_C2, a first wing portion TL31_W1, and a second wing portion TL31_W2. The body portion TL31_B of the third inorganic layer TL31 may be disposed on the third common electrode CE31 and may overlap the opening of the bank BN and the third light-emitting area EA3. The first connection portion TL31_C1 of the third inorganic layer TL31, which is a portion that connects the body portion TL31_B and the first wing portion TL31_W1, may be disposed in a space between the second wing portion TL21_W2 of the second inorganic layer TL21 and the bank BN.

The first wing portion TL31_W1 of the third inorganic layer TL31, which is a portion protruding from the first connection portion TL31_C1, may be disposed on the second wing portion TL21_W2 of the second inorganic layer TL21 and may be spaced apart from an upper surface TL21_S10 of the second wing portion TL21_W2 of the second inorganic layer TL21. The second connection portion TL31_C2 of the third inorganic layer TL31, which is a portion that connects the body portion TL31_B and the second wing portion TL31_W2, may be disposed in a space between the first wing portion TL11_W1 of the first inorganic layer TL11 and the bank BN. The second wing portion TL31_W2 of the third inorganic layer TL31, which is a portion protruding from the second connection portion TL31_C2, may be disposed on the first wing portion TL11_W1 of the first inorganic layer TL11 and may be spaced apart from an upper surface TL11_S9 of the first wing portion TL11_W1 of the first inorganic layer TL11.

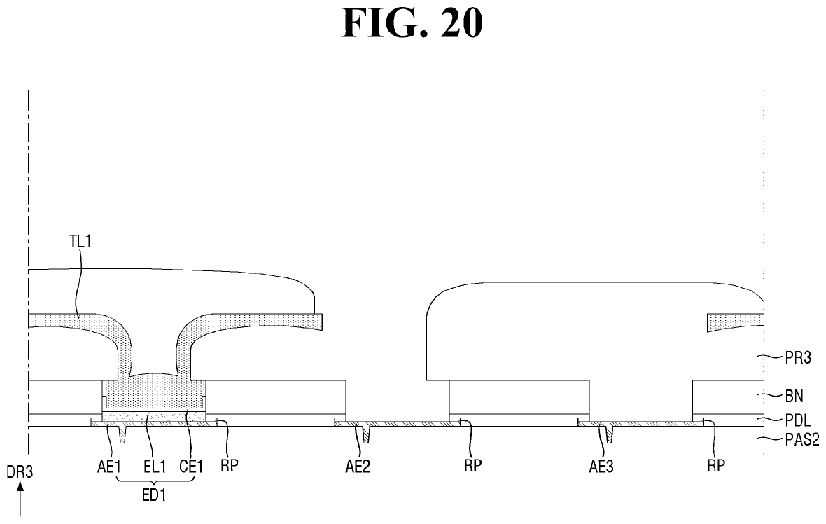

During the fabricating process, since there is an undercut structure on a lower side of the first inorganic layer TL11, the second inorganic layer TL21, and a photoresist pattern (′PR1′ in FIG. 12, ‘PR3’ in FIG. 20), the material deposited on the front surface may not be connected and may be disconnected. With a deposition and etching process without a mask process, the light-emitting layers EL1, EL21, and EL31 and the common electrodes CE1, CE21, and CE31 spaced apart for each of the light-emitting areas EA1, EA2, and EA3 may be formed.

The photoresist is formed and then removed during the fabricating process, and the second inorganic layer TL21 and the third inorganic layer TL31 may be formed in the positions where the photoresist is removed. The photoresist has a tip structure including a side surface protruding more than the bank BN and is then removed. The second inorganic layer TL2 and the third inorganic layer TL31 may have a tip structure with a side surface protruding more than the side surface of the bank BN.

A side surface TL21_S3 of the connection portion TL21_C1 of the second inorganic layer TL21 may further protrude toward the center of the first light-emitting area EA1 than the second side surface BN_S2 of the bank BN. A portion of the second inorganic layer TL21 may overlap the first light-emitting area EA1, and the side surface TL21_S3 of the connection portion TL21_C1 of the second inorganic layer TL21 may overlap the first pixel electrode AE1.

A side surface TL31_S3 of the first connection portion TL31_C1 of the third inorganic layer TL31 may further protrude toward the center of the second light-emitting area EA2 than the fourth side surface BN_S4 of the bank BN. A portion of the third inorganic layer TL31 may overlap the second light-emitting area EA2, and the side surface TL31_S3 of the first connection portion TL31_C1 of the third inorganic layer TL31 may overlap the second pixel electrode AE2.

A side surface TL31_S4 of the second connection portion TL31_C2 of the third inorganic layer TL31 may further protrude toward the center of the second light-emitting area EA2 than the first side surface BN_S1 of the bank BN. A portion of the third inorganic layer TL31 may overlap the first light-emitting area EA1, and the side surface TL31_S4 of the second connection portion TL31_C2 of the third inorganic layer TL31 may overlap the first pixel electrode AE1.

The first to third inorganic layers TL11, TL21, and TL31 may completely cover the upper surface of the light-emitting element layer EML in the display area DA. The first to third inorganic layers TL11, TL21, and TL31 may contact each other. Bonding between inorganic materials on an outer surface of the light-emitting element layer EML may improve encapsulation characteristics of the display device 10. An upper surface TL11_S2 of the body portion TL11_B of the first inorganic layer TL11, undercut surfaces TL11_S4 and TL11_S6 of the second wing portion TL11_W2, and a side surface TL11_S8 of the second wing portion TL11_W2 may contact surfaces TL21_S1, TL21_S3, TL21_S5, and TL21_S7 of the connection portion TL21_C1 of the second inorganic layer TL21. An upper surface TL21_S2 of the body portion TL21_B of the second inorganic layer TL21, undercut surfaces TL21_S4 and TL21_S6 of the second wing portion TL21_W2, and a side surface TL21_S8 of the second wing portion TL21_W2 may contact surfaces TL31_S1, TL31_S3, TL31_S5, and TL31_S7 of the first connection portion TL31_C1 of the third inorganic layer TL31. An upper surface TL11_S1 of the body portion TL11_B of the first inorganic layer TL11, undercut surfaces TL11_S3 and TL11_S5 of the first wing portion TL11_W1, and a side surface TL11_S7 of the first wing portion TL11_W1 may contact surfaces TL31_S2, TL31_S4, TL31_S6, and TL31_S8 of the second connection portion TL31_C2 of the third inorganic layer TL31.

The wings TL11_W1 and TL11_W2 of the first inorganic layer TL11 may short-circuit the second light-emitting layer EL21 and the second common electrode CE21 when the second light-emitting layer EL21 and the second common electrode CE21 are deposited. The second wing portion TL11_W2 of the first inorganic layer TL11 may overlap the second light-emitting layer EL21 and the second common electrode CE21 in the thickness direction DR3 of the substrate SUB.

The first wing portion TL11_W1 of the first inorganic layer TL11 and the wing portions TL21_W1 and TL11_W2 of the second inorganic layer TL21 may short-circuit the third light-emitting layer EL31 and the third common electrode CE31 when the third light-emitting layer EL31 and the third common electrode CE31 are deposited. The first wing portion TL11_W1 of the first inorganic layer TL11 and the second wing portion TL21_W2 of the second inorganic layer TL21 may overlap the third light-emitting layer EL31 and the third common electrode CE31 in the thickness direction DR3 of the substrate SUB. In an embodiment, the wing portions TL21_W1 of the second inorganic layer TL21 may include surfaces TL21_S9, TL_S11 and TL_S12.

The organic encapsulation layer TFE2 is disposed on the lower inorganic encapsulation layers TL11, TL21, and TL31. A portion of the organic encapsulation layer TFE2 may be disposed between the wing portions of the first to third inorganic layers TL11, TL21, and TL31. The organic encapsulation layer TFE2 may be disposed between the first wing portion TL11_W1 of the first inorganic layer TL11 and the second wing portion TL31_W2 of the third inorganic layer TL31, between the second wing portion TL11_W2 of the first inorganic layer TL11 and the first wing portion TL21_W1 of the second inorganic layer TL21, and between the second wing portion TL21_W2 of the second inorganic layer TL21 and the first wing portion TL31_W1 of the third inorganic layer TL31. The organic encapsulation layer TFE2 may not be in direct contact with the bank BN in the display area DA. In an embodiment, the first wing portion TL31_W1 of the third inorganic layer TL31 may include surfaces TL31_S9, TL31_S11 and TL31_S13. In an embodiment, the second wing portion TL31_W2 of the third inorganic layer TL31 may include surfaces TL31_S10, TL31_S12 and TL31_S14.

The upper inorganic encapsulation layer TFE3 may be disposed on the organic encapsulation layer TFE2. The upper inorganic encapsulation layer TFE3 may include aluminum oxide, titanium oxide, tantalum oxide, hafnium oxide, zinc oxide, silicon oxide, silicon nitride, and/or silicon oxynitride.

A light-blocking layer (not illustrated) may be optionally disposed on the thin film encapsulation layer TFEL. The light-blocking layer may be disposed between the light-emitting areas EA1, EA2, and EA3. The light-blocking layer may include a light absorbing material. In an embodiment, the light-blocking layer may include an inorganic black pigment or an organic black pigment, for example. The inorganic black pigment may be carbon black, and the organic black pigment may include at least one of lactam black, perylene black, and aniline black, but is not limited thereto. The light-blocking layer may prevent visible light from permeating and mixing colors between the first to third light-emitting areas EA1, EA2, and EA3, thereby improving a color reproduction rate of the display device 10.

The display device 10 may include a plurality of color filters CF1, CF2, and CF3 disposed on the light-emitting areas EA1, EA2, and EA3. Each of the plurality of color filters CF1, CF2, and CF3 may include a filtering pattern area and a light-blocking area. The filtering pattern area may be formed to overlap the light-emitting areas EA1, EA2, and EA3, and may form a light output area from which light emitted from the light-emitting areas EA1, EA2, and EA3 is emitted. The light-blocking area is an area where light may not transmit through because the plurality of color filters CF1, CF2, and CF3 are stacked thereon.

The color filters CF1, CF2, and CF3 may include a first color filter CF1, a second color filter CF2, and a third color filter CF3 disposed to respectively correspond to different light-emitting areas EA1, EA2, and EA3. The color filters CF1, CF2, and CF3 may include a colorant such as a dye or pigment that absorbs light in a wavelength band other than light in a predetermined wavelength band, and may be disposed to correspond to the colors of light emitted from the light-emitting areas EA1, EA2, and EA3. In an embodiment, the first color filter CF1 may be a red color filter that is disposed to overlap the first light-emitting area EA1 and transmits only first light of a red color, for example. The second color filter CF2 may be a green color filter that is disposed to overlap the second light-emitting area EA2 and transmits only second light of a green color, and the third color filter CF3 may be a blue color filter that is disposed to overlap the third light-emitting area EA3 and transmits only third light of a blue color.

In the display device 10, as the color filters CF1, CF2, and CF3 are disposed to overlap each other, intensity of reflected light caused by external light may be reduced. Furthermore, the color of light reflected by external light may also be controlled by adjusting the arrangement, shape, and area of the color filters CF1, CF2, and CF3 in a plan view.

An overcoat layer OC may be disposed on the color filters CF1, CF2, and CF3 to planarize upper ends of the color filters CF1, CF2, and CF3. The overcoat layer OC may be a colorless light-transmitting layer having no color in a visible light band. In an embodiment, the overcoat layer OC may include a colorless light-transmitting organic material such as an acryl-based resin, for example.

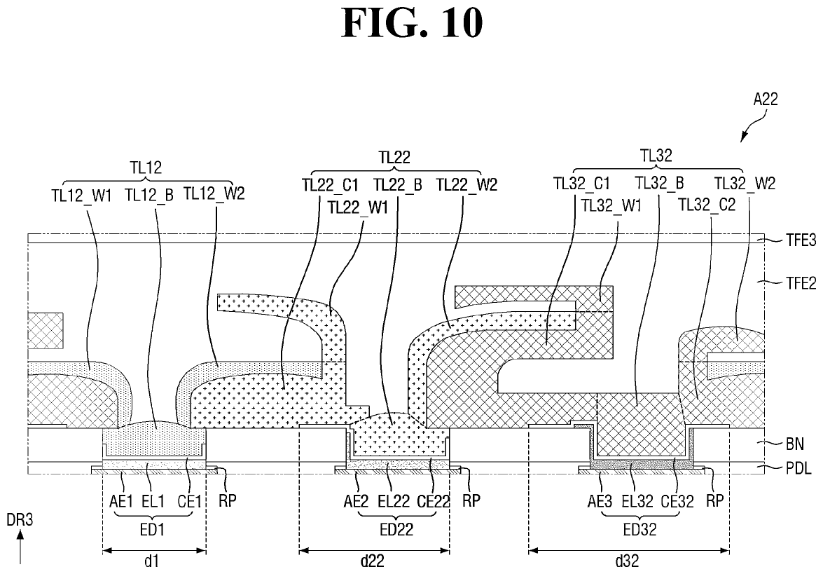

FIG. 10 is a cross-sectional view illustrating another embodiment of a portion A22 of the display device 10. Wing portions TL12_W1 and TL12_W2 of a first inorganic layer TL12 and wing portions TL22_W1 and TL22_W2 of a second inorganic layer TL22 in FIG. have a wider width than those in FIG. 6. As the width of the wing portion TL12_W1, TL12_W2, TL22_W1, and TL22_W2 increases, the width and area of a second light-emitting layer EL22, a second common electrode CE22, a third light-emitting layer EL32, and a third common electrode CE32 disposed on the bank BN are reduced. A width d22 of the second common electrode CE22 in FIG. 10 may be smaller than the width d21 of the second common electrode CE21 in FIG. 6. A width d32 of the third common electrode CE32 in FIG. 10 may be smaller than the width d31 of the third common electrode CE31 in FIG. 6. The second light-emitting layer EL22 in FIG. 10 may not be deposited up to the upper surface of the bank BN, and one end of the second light-emitting layer EL22 may be disposed on the side surface of the bank BN up to a higher position than an opposite end of the second light-emitting layer EL22. In an embodiment, the first inorganic layer TL12 may further include a body portion TL12_B and a first wing portion TL12_W1, the second inorganic layer TL22 may further include a body portion TL22_B and a first wing portion TL22_W1, and the third inorganic layer TL32 may further include a body portion TL32_B and a first wing portion TL32_W1. In an embodiment, a second light-emitting element ED22 may include a second emitting layer EL22 and a second common electrode CE22. In an embodiment, a third light-emitting element ED32 may include a third emitting layer EL32 and a third common electrode CE32.

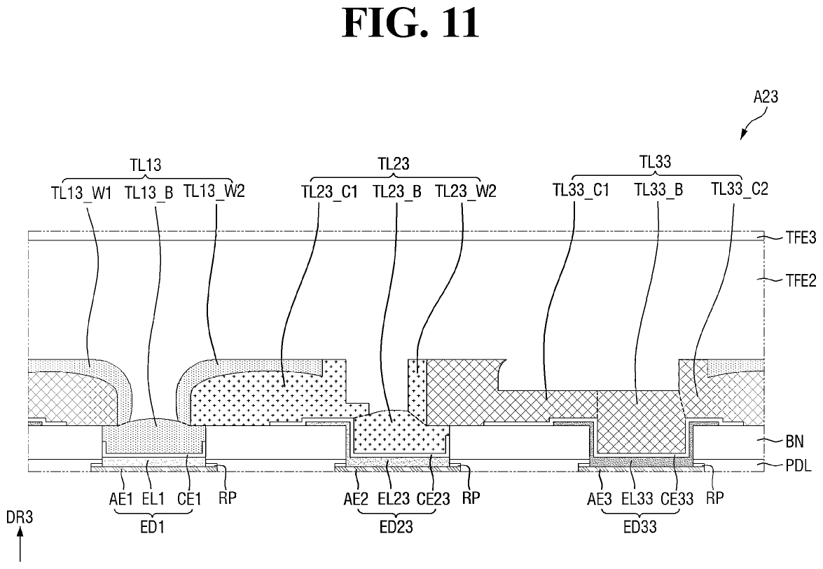

FIG. 11 is a cross-sectional view illustrating another embodiment of a portion A23 of the display device 10. FIG. 11 is different from FIG. 6 in that some wing portions of the first to third inorganic layers TL13, TL23, and TL33 are removed. After forming the first to third inorganic layers TL11, TL21, and TL31 as illustrated in FIG. 6, some wing portions disposed on an upper side may be removed through a dry etching process. The second inorganic layer TL23 in FIG. 11 does not have a wing portion on an upper side of a second wing portion TL13_W2 of the first inorganic layer TL13, and may include a wing portion TL23_W2 disposed on a side surface of a first connection portion TL33_C1 of the third inorganic layer TL33. The third inorganic layer TL33 does not have a wing portion on an upper side of the second wing portion TL13_W2 of the first inorganic layer TL13 and the wing portion TL23_W2 of the second inorganic layer TL23. By adjusting the dry etching process, it is possible to control the removal amount and remaining shape of the wing portions of the first to third inorganic layers TL13, TL23, and TL33. In an embodiment, the first inorganic layer TL13 may further include a body portion TL13_B and a first wing portion TL13_W1, the second inorganic layer TL23 may further include a body portion TL23_B and a first wing portion TL23_W1, and the third inorganic layer TL33 may further include a body portion TL33_B and a first wing portion TL33_W1. In an embodiment, a second light-emitting element ED23 may include a second emitting layer EL23 and a second common electrode CE23. In an embodiment, a third light-emitting element ED33 may include a third emitting layer EL33 and a third common electrode CE33.

Hereinafter, a process of fabricating a display device 10 in an embodiment will be described with reference to other drawings.

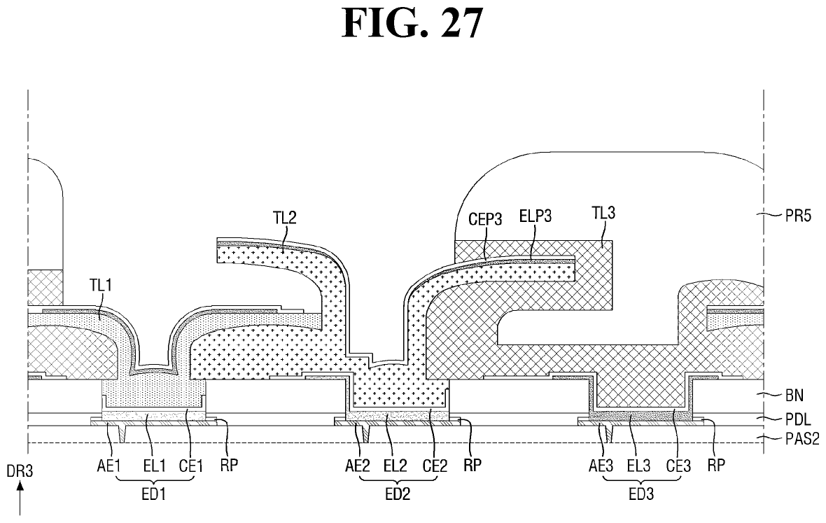

FIGS. 12 to 29 are cross-sectional views sequentially illustrating an embodiment of processes for fabricating a display device.

FIGS. 12 to 29 schematically illustrate a process of forming a bank structure and light-emitting elements ED as a light-emitting element layer EML of the display device 10, and a thin film encapsulation layer TFEL. Hereinafter, a description of a formation process of each layer in the process of fabricating the display device 10 will be omitted, and a formation order of each layer will be described.

Referring to FIG. 12, a plurality of pixel electrodes AE1, AE2, and AE3, a sacrificial layer SFL, a pixel defining material layer PDLL, and a bank material layer BNL spaced entirely apart are formed on a second passivation layer PAS2. First photoresist patterns PR1 may be spaced apart from each other on the bank material layer BNL, and may be disposed to expose areas overlapping the plurality of pixel electrodes AE1, AE2, and AE3.

Although not illustrated in the drawings, the thin film transistor layer TFTL may be disposed on the substrate SUB, and a structure of the thin film transistor TFTL is the same as that described above with reference to FIG. 5. A detailed description thereof is omitted.

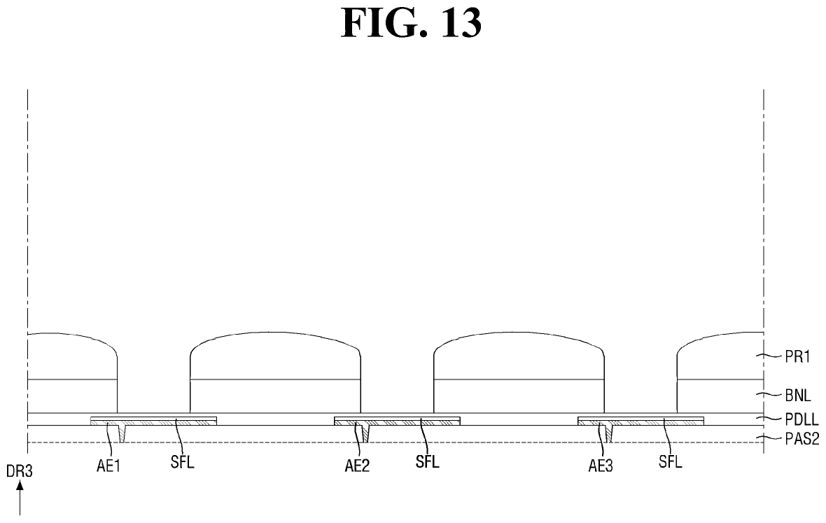

Next, referring to FIG. 13, a first etching process of etching a portion of the bank material layer BNL using the first photoresist pattern PR1 as a mask is performed. Holes may be formed through the first etching process. In an embodiment, the first etching process may be performed as anisotropic dry etching. The hole may be formed in the areas that overlap the plurality of pixel electrodes AE1, AE2, and AE3.

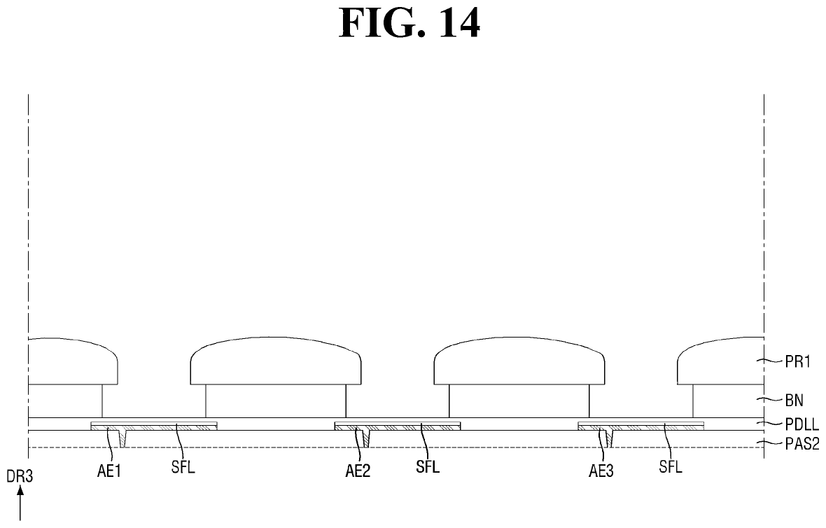

Next, referring to FIG. 14, an undercut structure of the bank BN may be formed by etching a side surface of the bank material layer BNL through a second etching process. A side surface of the first photoresist pattern PR1 may be formed to protrude more than a side surface of the bank BN. In an embodiment, the second etching process may be isotropic wet etching. The second etching process may use an alkaline etchant.

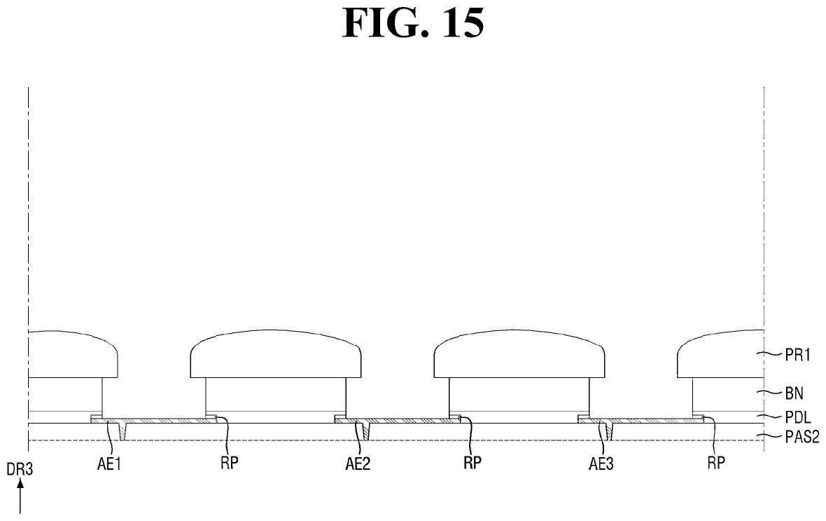

Next, as illustrated in FIG. 15, a portion of the pixel defining material layer PDLL and sacrificial layer SFL may be removed through a third etching process. The third etching process may include a dry etching step of removing a portion of the pixel defining material layer PDLL, and a wet etching step of forming a residual pattern RP by removing a portion of the sacrificial layer SFL. In the step of removing the pixel defining material layer PDLL, the sacrificial layer SFL may protect the pixel electrodes AE1, AE2, and AE3 from plasma.

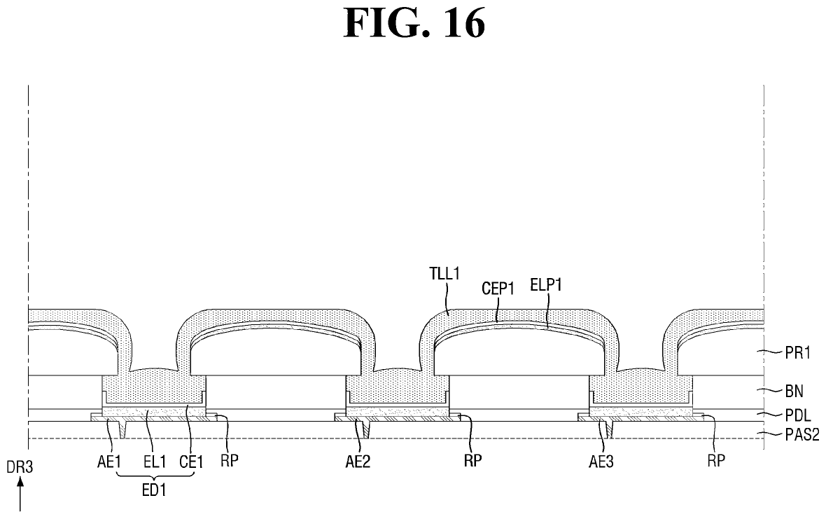

Next, as illustrated in FIG. 16, a first light-emitting element ED1 is formed by depositing a first light-emitting layer EL1 and a first common electrode CE1 on the first pixel electrode AE1. In this case, since the first light-emitting layer EL1 and the first common electrode CE1 are formed on the entirety of the surface of the substrate SUB, a first light-emitting pattern ELP1 and a first electrode pattern CEP1 may also be formed on the first photoresist pattern PR1.

By the tip of the first photoresist pattern PR1, the first light-emitting layer EL1 and the first light-emitting pattern ELP1 may be separated and the first common electrode CE1 and the first electrode pattern CEP1 may be separated. At the same time as forming the first light-emitting layer EL1 on the first pixel electrode AE1, the first light-emitting pattern ELP1 may be formed on the first photoresist pattern PR1. At the same time as forming the first common electrode CE1 on the first light-emitting layer EL1, the first electrode pattern CEP1 may be formed on the first light-emitting pattern ELP1.

The first light-emitting layer EL1 and the first common electrode CE1 may be formed through a thermal deposition process. Within the undercut structure of the bank BN, the material may not be deposited smoothly due to the tip of the first photoresist pattern PR1. However, since the materials of the first light-emitting layer EL1 and the first common electrode CE1 are deposited in an inclined direction rather than a direction perpendicular to the upper surface of the substrate, the deposition may also be performed on an area of covered by the tip of the first photoresist pattern PR1.

Compared to the deposition process of forming the light-emitting layer EL1, the deposition process of forming the common electrode CE1 may be performed to be inclined to be closer to a relatively horizontal direction. Accordingly, the common electrode CE1 may have a larger contact area with the side surface of the bank BN than the light-emitting layer EL1. In an alternative embodiment, the common electrode CE1 may be deposited to a higher position on the side surface of the bank BN than the light-emitting layer EL1.

Next, a first inorganic material layer TLL1 covering the first light-emitting element ED1 is formed. The first inorganic material layer TLL1 may be formed to completely cover outer surfaces of the first light-emitting element ED1, the bank BN1, the first photoresist pattern PR1, the first light-emitting pattern ELP1, and the first electrode pattern CEP1 without disconnected portions. Specifically, the first inorganic material layer TLL1 is formed on an upper surface of the first common electrode CE1, a side surface of the bank BN, a lower surface and a side surface of the first photoresist pattern PR1, and an upper surface of the first electrode pattern CEP1.

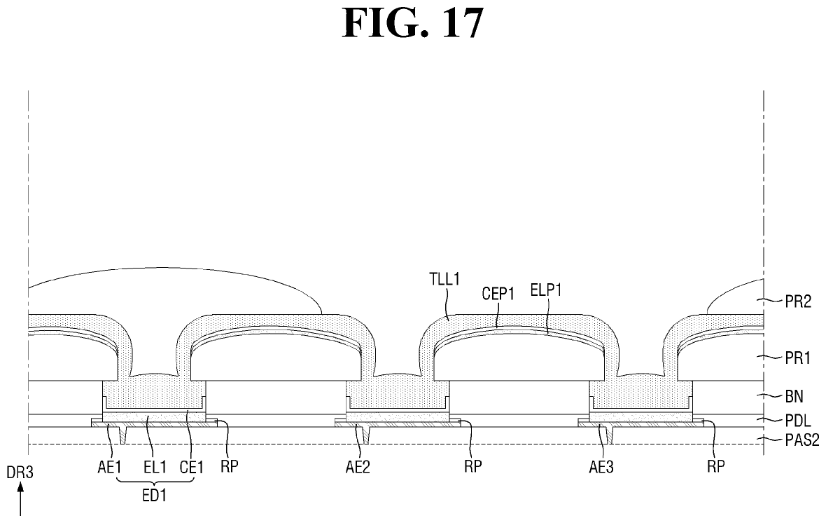

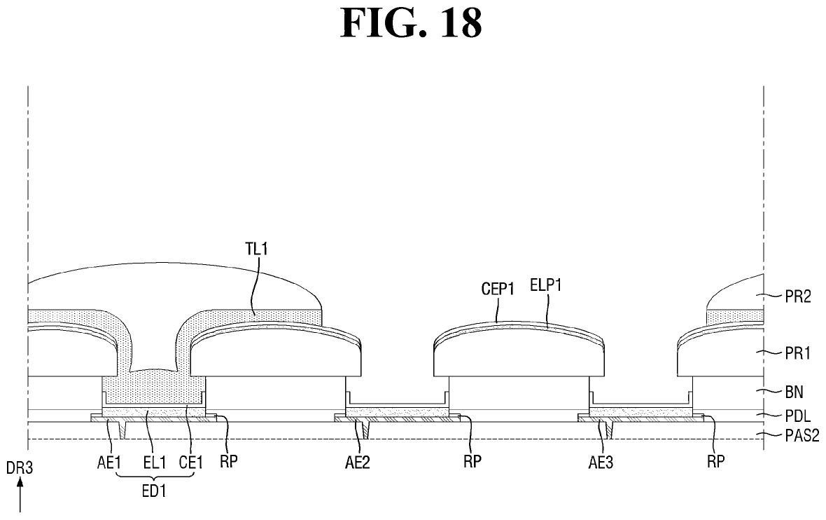

Next, referring to FIG. 17, a second photoresist pattern PR2 covering the first light-emitting element ED1 and a peripheral area thereof is applied. The second photoresist pattern PR2 may be applied up to a position close to the side surface of the bank BN adjacent to the second pixel area. Depending on the application area of the second photoresist pattern PR2, a length of the wing portion of the first inorganic layer TL1 (refer to FIG. 18, for example) formed later may be determined.

Next, referring to FIG. 18, a fourth etching process of exposing the first electrode pattern CEP1 by removing a portion of the first inorganic material layer TLL1 is performed. In an embodiment, the fourth etching process may include isotropic dry etching. The first inorganic material layer TLL1 that is not covered by the second photoresist pattern PR2 may be removed. First and second wing portions of the first inorganic layer TL1 may be obtained through the fourth etching process.

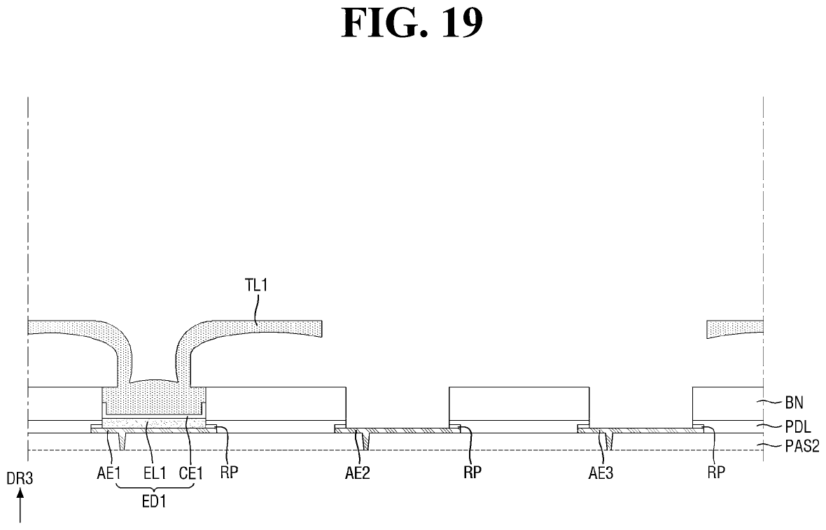

Next, referring to FIG. 19, a fifth etching process of removing the first and second photoresist patterns PR1 and PR2, the first light-emitting pattern ELP1, and the first electrode pattern CEP1 is performed. In an embodiment, the fifth etching process may be isotropic wet etching. Not only the first electrode pattern CEP1 and the first light-emitting pattern ELP1 disposed on the first photoresist pattern PR1, but also the first light-emitting pattern ELP1 and the first electrode pattern CEP1 of the second and third light-emitting areas EA2 and EA3 may be removed. The first photoresist pattern PR1, the first light-emitting pattern ELP1, and the first electrode pattern CEP1 disposed between the wing portion of the first inorganic layer TL1 and the bank BN may also be removed, and an undercut structure of the first inorganic layer TL1 may be formed. Through the fifth etching process, the upper surface of the bank BN may be exposed.

Next, as illustrated in FIG. 20, a third photoresist pattern PR3 covering the first light-emitting element ED1 and the third pixel electrode AE3 is applied. The third photoresist pattern PR3 may be disposed to expose the second pixel electrode AE2 and partially overlap the second pixel electrode AE2. The third photoresist pattern PR3 may have a tip structure in which a side surface thereof protrudes more than fourth side surface BN_S4 of the bank BN, and the bank BN may have an undercut structure on a lower surface of the tip.

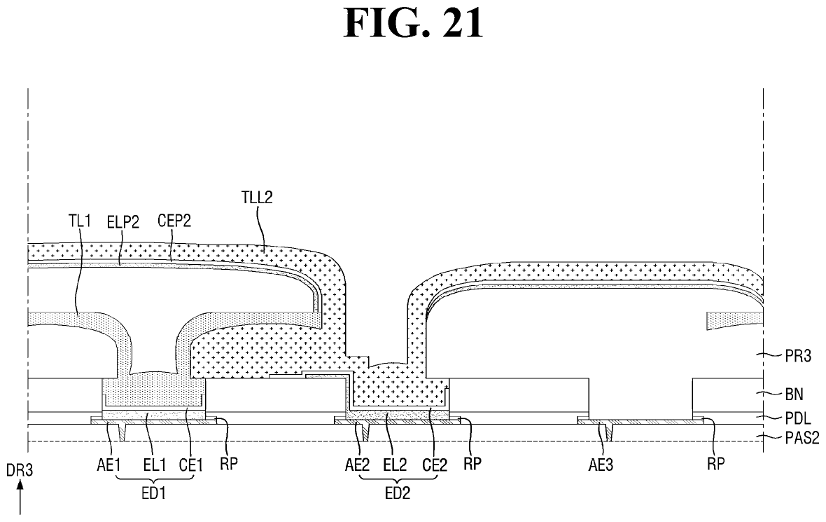

Next, referring to FIG. 21, a second light-emitting element ED2 is formed by depositing a second light-emitting layer EL2 and a second common electrode CE2 on the second pixel electrode AE2. Thereafter, a second inorganic material layer TLL2 covering the second light-emitting element ED2 is formed. In such a process, as illustrated in FIG. 16, the material is deposited on the entirety of the surface of the substrate SUB, but since the material is disconnected by the wing portion of the first inorganic layer TL1 and the tip of the third photoresist pattern PR3, upper and lower layers are separated. Since the side surface of the wing portion of the first inorganic layer TL1 does not protrude more than the third side surface BN_S3 of the bank BN, the second light-emitting layer EL2 and the second common electrode CE2 may also be formed on the upper surface of the bank BN. Depending on a length of the wing portion of the first inorganic layer TL1, the width and area of the second light-emitting layer EL2 and the second common electrode CE2 formed on the upper surface of the bank BN may vary. The second light-emitting pattern ELP2 and the second electrode pattern CEP2 may be disposed on the third photoresist pattern PR3.

Next, a second inorganic material layer TLL2 covering the second light-emitting element ED21 is formed. The second inorganic material layer TLL2 may also be formed in a space between the wing portion of the first inorganic layer TL1 and the bank, and may be formed to completely cover the upper and side surfaces of the bank BN, the second common electrode CE2, the second electrode pattern CEP2, and the first inorganic layer TL11 without disconnected portions.

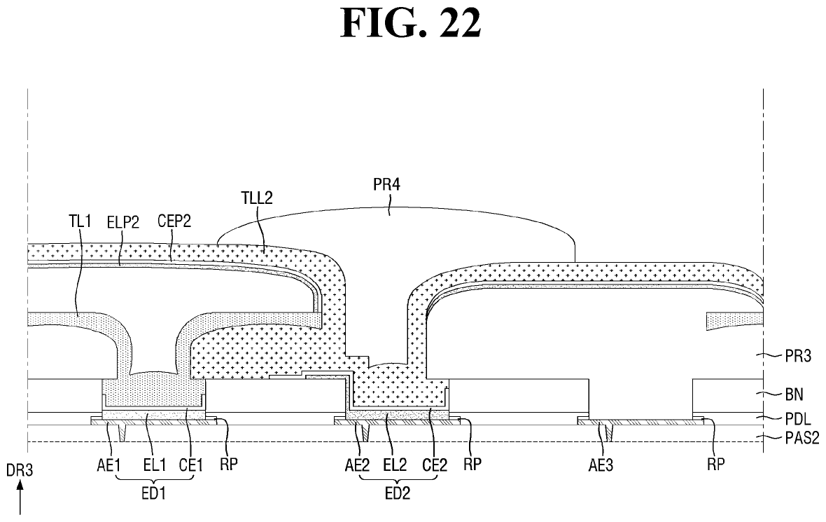

Next, as illustrated in FIG. 22, a fourth photoresist pattern PR4 covering the second light-emitting element ED2 and a peripheral area thereof is applied. The fourth photoresist pattern PR4 may be applied up to a position close to the side surface of the bank BN adjacent to the third pixel area. Depending on the application area of the fourth photoresist pattern PR4, a length of the wing portion of the second inorganic layer TL2 formed later may be determined.

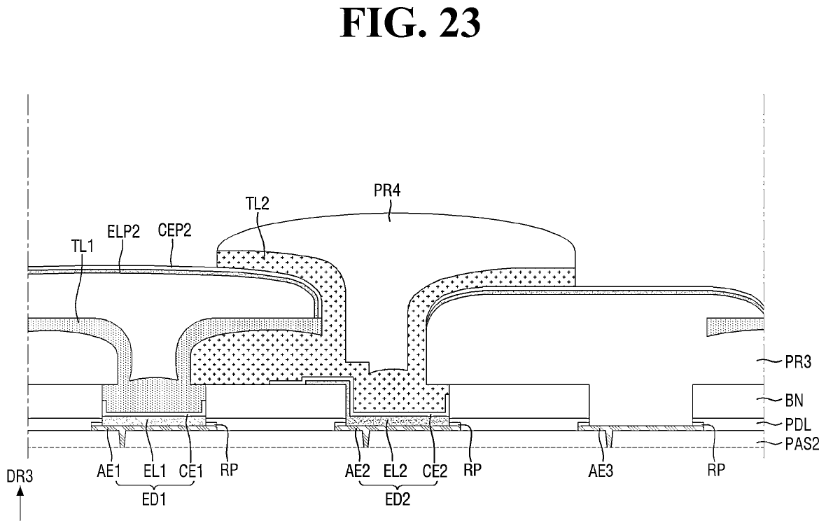

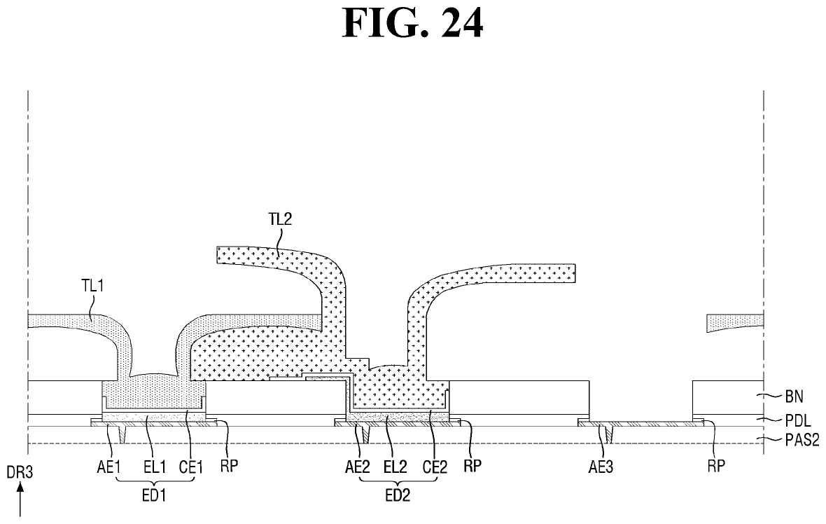

Next, referring to FIGS. 23 and 24, a portion of the second inorganic material layer TLL2 may be removed, and the third and fourth photoresist patterns PR3 and PR4, the second light-emitting pattern ELP2, and the second electrode pattern CEP2 may be removed. Such a process may be performed similarly to that described in FIGS. 18 and 19. The second inorganic layer TL2 having a wing portion may be formed.

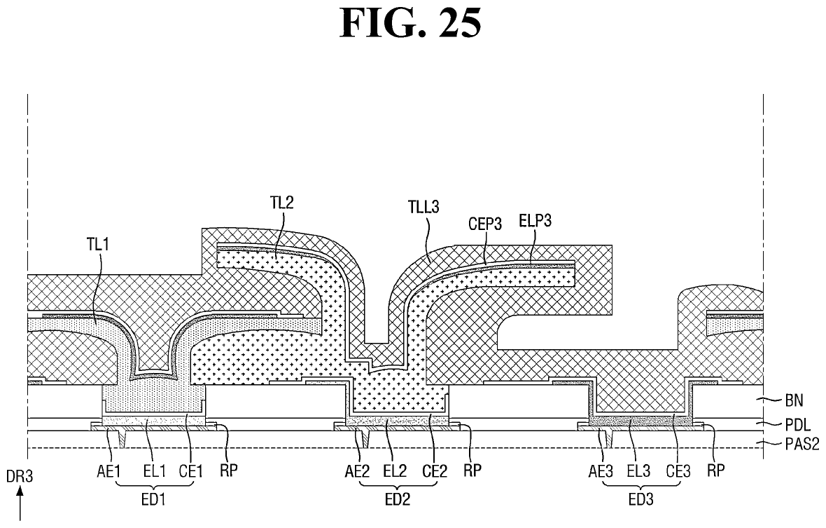

Next, as illustrated in FIG. 25, a third light-emitting layer EL3, a third light-emitting pattern ELP3, a third common electrode CE3, a third electrode pattern CEP3, and a third inorganic material layer TLL3 may be formed. Such a process may be performed similarly to that described in FIG. 21, but it is different in that the deposition material is short-circuited by the wing portions of the first and third inorganic layers TL1 and TL3 rather than the tip of the photoresist pattern.

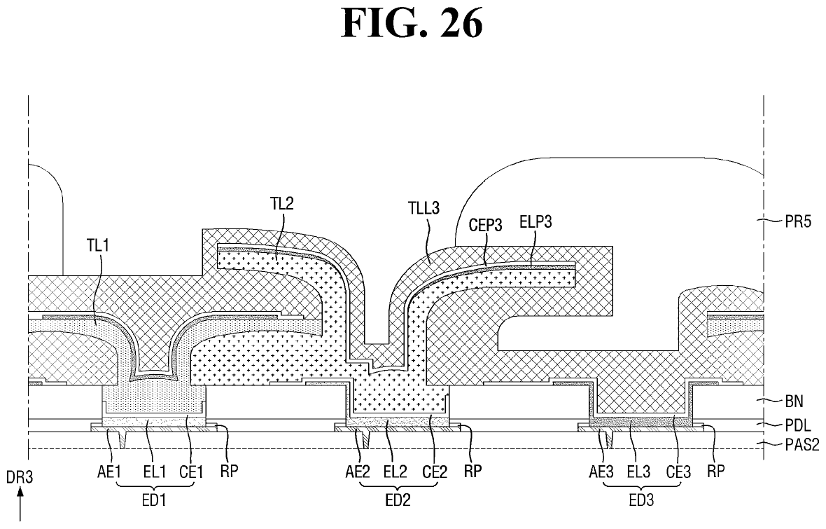

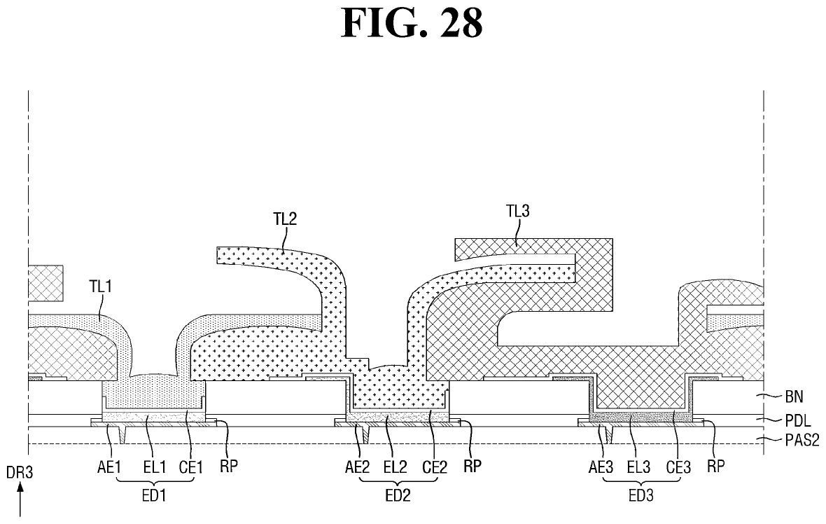

Next, as illustrated in FIGS. 26 to 28, by removing the third light-emitting pattern ELP3 and the third electrode pattern CEP3, the third inorganic layer TL3 including a wing portion may be obtained. When the fifth photoresist pattern PR5 covering the third light-emitting element ED3 and the peripheral area thereof is applied and the process as illustrated in FIGS. 23 and 24 is then repeated, first to third light-emitting elements ED1, ED2, and ED3 and first to third inorganic layers TL1, TL2, and TL3 as illustrated in FIG. 28 may be obtained.

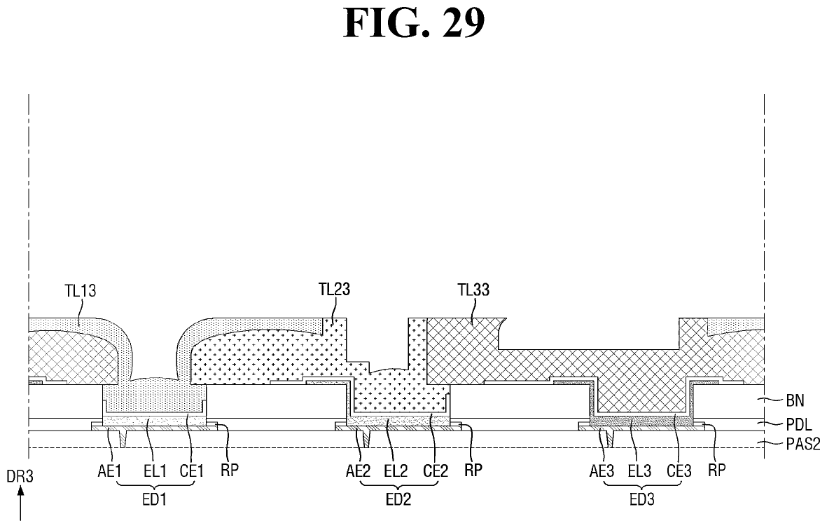

Optionally, when a dry etching process of removing a portion of the upper portion of the first to third inorganic layers TL1, TL2, and TL3 of FIG. 28, inorganic layers TL13, TL23, and TL33 with a portion of the wing portion removed as illustrated in FIGS. 29 and 11 may be obtained.

Next, although not illustrated in the drawings, a display device 10 is fabricated by forming an organic encapsulation layer TFE2 and an upper inorganic encapsulation layer TFE3 of the thin film encapsulation layer TFEL, a light-blocking layer, a color filter layer CFL, and an overcoat layer OC on the light-emitting elements ED1, ED21, and ED31 and the bank structure. Since the structure of the thin film encapsulation layer TFEL, the light-blocking layer, the color filter layer CFL, and the overcoat layer OC is the same as described above, a detailed description thereof will be omitted.

The embodiments of the disclosure have been described hereinabove with reference to the accompanying drawings, but it will be understood by one of ordinary skill in the art to which the disclosure pertains that various modifications and alterations may be made without departing from the technical spirit or essential feature of the disclosure. Therefore, it should be understood that the embodiments described above are illustrative in all features and not restrictive.

What is claimed is:

1. A display device comprising:
a substrate;
a first pixel electrode and a second pixel electrode spaced apart from each other on the substrate;
a pixel defining layer disposed on the substrate and exposing the first pixel electrode and the second pixel electrode;
a bank disposed on the pixel defining layer;
a first light-emitting layer disposed on the first pixel electrode;
a second light-emitting layer disposed on the second pixel electrode;
a first common electrode disposed on the first light-emitting layer; and
a second common electrode disposed on the second light-emitting layer and the bank and spaced apart from the first common electrode,
wherein a width of the first common electrode and a width of the second common electrode are different from each other.

2. The display device of claim 1, wherein the width of the first common electrode is smaller than the width of the second common electrode.

3. The display device of claim 1, wherein the width of the first common electrode is smaller than a width of the first pixel electrode, and
the width of the second common electrode is smaller than a width of the second pixel electrode.

4. The display device of claim 1, wherein the first common electrode is disposed on at least a portion of a first side surface of the bank and at least a portion of a second side surface different from the first side surface of the bank, and
the second common electrode is disposed on an entirety of a third side surface of the bank, at least a portion of a fourth surface different from the third side surface of the bank, and at least a portion of an upper surface of the bank.

5. The display device of claim 1, wherein the bank is a single film of metal or metal alloy.

6. The display device of claim 1, further comprising:
a first inorganic layer comprising a body portion disposed on the first common electrode, and a wing portion disposed on the bank and spaced apart from an upper surface of the bank; and
a second inorganic layer comprising a body portion disposed on the second common electrode, and a connection portion disposed between the bank and the wing portion of the first inorganic layer.

7. The display device of claim 6, wherein the connection portion of the second inorganic layer comprises a side surface which further protrudes than a side surface of the bank and overlaps the first pixel electrode.

8. The display device of claim 6, wherein the wing portion of the first inorganic layer overlaps the second common electrode in a thickness direction of the substrate.

9. The display device of claim 6, wherein a lower surface of the connection portion of the second inorganic layer contacts the first inorganic layer.

10. The display device of claim 6, wherein the second inorganic layer further comprises:
a first wing portion disposed on the wing portion of the first inorganic layer and spaced apart from an upper surface of the wing portion of the first inorganic layer; and
a second wing portion disposed on the bank and spaced apart from the upper surface of the bank.

11. The display device of claim 6, further comprising:
a third pixel electrode disposed on the substrate and spaced apart from the first pixel electrode and the second pixel electrode;
a third light-emitting layer disposed on the third pixel electrode; and
a third common electrode disposed on the third light-emitting layer and the bank and spaced apart from the first common electrode and the second common electrode.

12. The display device of claim 11, wherein the third common electrode is disposed on an entirety of a fifth side surface of the bank, an entirety of a sixth side surface different from the fifth side surface of the bank, and at least a portion of the upper surface of the bank.

13. The display device of claim 12, wherein a width of the third common electrode disposed on the upper surface of the bank is different from a width of the second common electrode disposed on the upper surface of the bank.

14. The display device of claim 10, further comprising an organic encapsulation layer disposed between the wing portion of the first inorganic layer and the first wing portion of the second inorganic layer.

15. A display device comprising:
a substrate;
a first pixel electrode, a second pixel electrode, and a third pixel electrode spaced apart from each other on the substrate;
a pixel defining layer disposed on the substrate and exposing the first pixel electrode, the second pixel electrode, and the third pixel electrode;
a bank disposed on the pixel defining layer;
a first light-emitting layer on the first pixel electrode and a first common electrode on the first light-emitting layer;
a second light-emitting layer disposed on the second pixel electrode and a second common electrode on the second light-emitting layer;
a third light-emitting layer disposed on the third pixel electrode and a third common electrode on the third light-emitting layer; and
a first inorganic layer comprising a body portion disposed on the first common electrode, and a wing portion disposed on the bank and spaced apart from an upper surface of the bank,
wherein the wing portion of the first inorganic layer overlaps the second common electrode and the third common electrode in a thickness direction of the substrate.

16. The display device of claim 15, further comprising a second inorganic layer comprising a body portion disposed on the second common electrode, and a connection portion disposed between the bank and the wing portion of the first inorganic layer,
wherein the connection portion of the second inorganic layer comprises a side surface which further protrudes than a side surface of the bank and overlaps the first pixel electrode.

17. The display device of claim 15, wherein the first common electrode, the second common electrode, and the third common electrode have different cross-sectional shapes from each other.

18. A method for fabrication of a display device, the method comprising:
forming a plurality of pixel electrodes spaced apart from each other on a substrate, forming a pixel defining material layer on the plurality of pixel electrodes, and forming a bank material layer on the pixel defining material layer;
forming a first photoresist pattern on the bank material layer;
etching the bank material layer which is not covered by the first photoresist pattern; and
etching a side surface of the bank material layer and exposing a lower surface of the first photoresist pattern.

19. The method of claim 18, wherein the etching the bank material layer which is not covered by the first photoresist pattern comprises an anisotropic dry etching process, and
the etching the side surface of the bank material layer and the exposing the lower surface of the first photoresist pattern comprises an isotropic wet etching process.

20. The method of claim 18, further comprising:
forming a first light-emitting layer on a first pixel electrode among the plurality of pixel electrodes and a first light-emitting pattern on the first photoresist pattern;
forming a first common electrode on the first light-emitting layer and a first electrode pattern on the first light-emitting pattern;
forming a first inorganic material layer on the first common electrode and the first electrode pattern;
forming a second photoresist pattern on the first inorganic material layer overlapping the first pixel electrode;
removing the first inorganic material layer which is not covered by the second photoresist pattern; and
removing the first photoresist pattern, the second photoresist pattern, the first light-emitting pattern, and the first electrode pattern.
